(19) United States
(12) Patent Application Publication
(10) Pub. No.: US 2024/0105745 A1
(43) Pub. Date: Mar. 28, 2024

(54) IMAGE SENSOR

(71) Applicant: SAMSUNG ELECTRONICS CO., LTD., Suwon-si (KR)

(72) Inventors: Dongchan KIM, Suwon-si (KR); Chanho PARK, Suwon-si (KR); Hongkyu PARK, Suwon-si (KR); Byoungho KWON, Suwon-si (KR); Kyungrae BYUN, Suwon-si (KR); Minhwan JEON, Suwon-si (KR); Hwiyoung JEONG, Suwon-si (KR)

(73) Assignee: SAMSUNG ELECTRONICS CO., LTD., Suwon-si (KR)

(21) Appl. No.: 18/241,478

(22) Filed: Sep. 1, 2023

(30) Foreign Application Priority Data
Sep. 27, 2022 (KR) 10-2022-0122869

(51) Int. Cl. H01L 27/146

(52) U.S. Cl. CPC H01L 27/14625; H01L 27/14621

(57) ABSTRACT

Provided is an image sensor including a sensor substrate, a spacer layer on the sensor substrate, and a color separating lens array on the spacer layer and configured to separate light based on a wavelength of the light, wherein the color separating lens array includes a first lens layer including a plurality of first nano posts and a first peripheral material layer around the plurality of first nano posts, a chemical mechanical polishing (CMP) stop layer on the first peripheral material layer, an etch stop layer on an upper surface of the CMP stop layer and directly on an upper surface of each first nano post of the plurality of first nano posts, and a second lens layer on the etch stop layer, the second lens layer including a plurality of second nano posts and a second peripheral material layer around the plurality of second nano posts.

### CROSS-REFERENCE TO RELATED APPLICATION

This application is based on and claims priority under 35 U. S. C. § 119 to Korean Patent Application No. 10-2022-0122869, filed on Sep. 27, 2022, in the Korean Intellectual Property Office, the disclosure of which is incorporated by reference herein in its entirety.

### BACKGROUND

The present disclosure relates to an image sensor and a method of manufacturing the same.

Image sensors which capture an image (or a picture) and convert the captured image into an electrical signal may be applied to cameras equipped in vehicles, security devices, and robots, in addition to general consumer electronic equipment such as digital cameras, cameras for portable phones, and portable camcorders.

To enhance a signal-to-noise ratio of image sensors, a color separating lens array to replace a micro lens array has been developed. The color separating lens array may spatially separate red light, green light, and blue light by using a spatial contrast of a refractive index, collect the separated light, and transfer the collected light to pixels.

### SUMMARY

One or more embodiments provide an image sensor including a color separating lens array which may separate incident light by wavelengths and may concentrate separated pieces of light.

According to an aspect of an embodiment, there is provided an image sensor including a sensor substrate, a spacer layer on the sensor substrate, and a color separating lens array on the spacer layer and configured to separate light based on a wavelength of the light, wherein the color separating lens array includes a first lens layer including a plurality of first nano posts and a first peripheral material layer around the plurality of first nano posts, a chemical mechanical polishing (CMP) stop layer on the first peripheral material layer, an etch stop layer on an upper surface of the CMP stop layer and directly on an upper surface of each first nano post of the plurality of first nano posts, and a second lens layer on the etch stop layer, the second lens layer including a plurality of second nano posts and a second peripheral material layer around the plurality of second nano posts.

According to another aspect of an embodiment, there is provided an image sensor including a sensor substrate including a plurality of light sensing cells, a spacer layer on the sensor substrate, a first etch stop layer on the spacer layer, and a color separating lens array on the first etch stop layer and configured to separate light based on a wavelength of the light, wherein the color separating lens array includes a first lens layer including a plurality of first nano posts and a first peripheral material layer around the plurality of first nano posts, a chemical mechanical polishing (CMP) stop layer on the first peripheral material layer, a second etch stop layer on an upper surface of the CMP stop layer and directly on an upper surface of each first nano post of the plurality of first nano posts, and a second lens layer on the second etch stop layer, the second lens layer including a plurality of second nano posts and a second peripheral material layer around the plurality of second nano posts.

According to yet another aspect of an embodiment, there is provided an image sensor including a sensor substrate including a first pixel configured to sense a first wavelength light and a second pixel configured to sense a second wavelength light, a transparent spacer layer on the sensor substrate, a first etch stop layer on the transparent spacer layer, and a color separating lens array on the first etch stop layer and configured to separate light based on a wavelength of the light, wherein the color separating lens array includes a first lens layer including a plurality of first nano posts and a first peripheral material layer around the plurality of first nano posts, a first chemical mechanical polishing (CMP) stop layer on the first peripheral material layer, a second etch stop layer on an upper surface of the first CMP stop layer and directly on an upper surface of each first nano post of the plurality of first nano posts, a second lens layer on the second etch stop layer, the second lens layer including a plurality of second nano posts and a second peripheral material layer around the plurality of second nano posts, and a second CMP stop layer on the second peripheral material layer.

### BRIEF DESCRIPTION OF THE DRAWINGS

Embodiments will be more clearly understood from the following detailed description taken in conjunction with the accompanying drawings in which:

FIG. 1 is a block diagram of an image sensor according to an embodiment;

FIGS. 2A and 2B are conceptual diagrams illustrating a structure and an operation of a color separating lens array included in an image sensor according to an embodiment;

FIG. 3 is a plan view illustrating color arrangement in a pixel array of an image sensor according to an embodiment;

FIGS. 4A and 4B are cross-sectional views illustrating different cross-sectional surfaces of a pixel array of the image sensor of FIG. 1;

FIG. 5A is a plan view illustrating an arrangement of a pixel correspondence region of a color separating lens array included in a pixel array, and FIG. 5B is a plan view illustrating a pixel arrangement of a sensor substrate included in a pixel array;

FIG. 6A shows phase profiles of green light and blue light passing through a color separating lens array in terms of the cross-sectional surface of FIG. 4A, FIG. 6B shows a phase at a center of pixel correspondence regions of green light passing through a color separating lens array, and FIG. 6C shows a phase at a center of pixel correspondence regions of blue light passing through a color separating lens array; FIG. 6D shows a traveling direction of green light incident on a first green light collection region, and FIG. 6E shows an array of the first green light collection region; FIG. 6F shows a traveling direction of blue light incident on a blue light collection region, and FIG. 6G shows an array of the blue light collection region;

FIG. 7A shows phase profiles of red light and green light passing through a color separating lens array, FIG. 7B shows a phase at a center of pixel correspondence regions of red light passing through a color separating lens array, and FIG. 7C shows a phase at a center of pixel correspondence regions of green light passing through a color separating lens array; FIG. 7D shows a traveling direction of red light incident on a red light collection region, and FIG. 7E shows an array of the red light collection region; FIG. 7F shows a traveling direction of green light incident on a second green light collection region, and FIG. 7G shows an array of the second green light collection region;

FIGS. 8A and 8B are cross-sectional views illustrating a pixel array of an image sensor according to an embodiment;

FIGS. 9A and 9B are cross-sectional views illustrating a pixel array of an image sensor according to an embodiment;

FIGS. 10A, 10B, 10C, and 10D are cross-sectional views illustrating a pixel array of an image sensor according to an embodiment;

FIGS. 11A, 11B, 11C, 11D, 11E, 11F, 11G, 11H, and 11I are cross-sectional views describing a method of manufacturing the image sensor of FIGS. 9A and 9B;

FIG. 12 is a block diagram illustrating an electronic device including an image sensor according to an embodiment; and

FIG. 13 is a block diagram illustrating a camera module included in the electronic device of FIG. 12.

### DETAILED DESCRIPTION

Hereinafter, embodiments will be described in detail with reference to the accompanying drawings. Described embodiments are merely examples, and the embodiments may be variously modified. Like reference numerals refer to like elements in the drawings, and a size of each element in the drawings may be exaggerated for clarity and convenience of description.

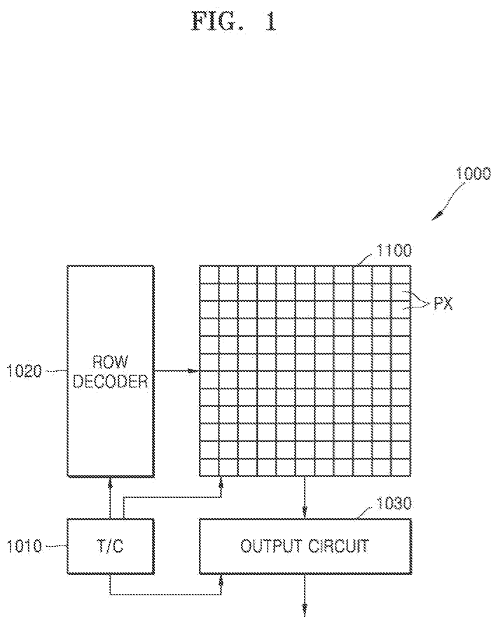

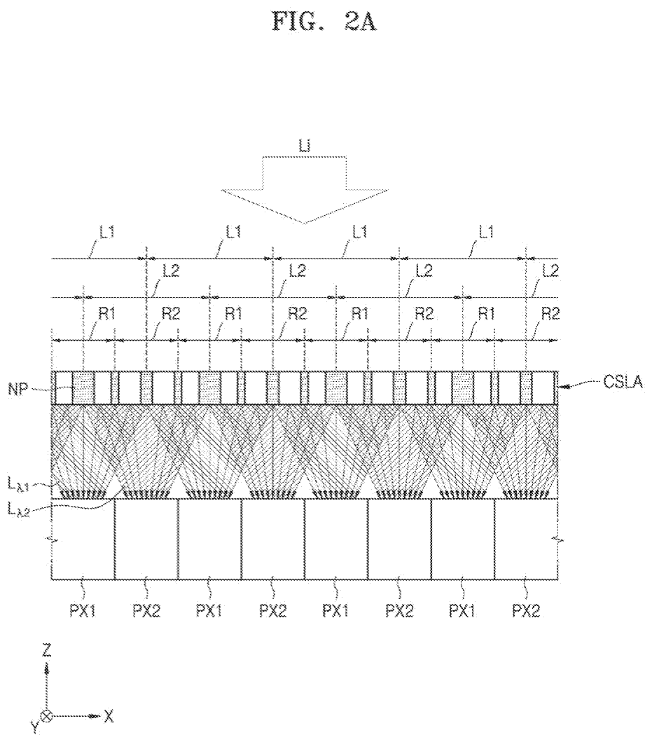

FIG. 1 is a block diagram of an image sensor 1000 according to an embodiment.

Referring to FIG. 1, the image sensor 1000 may include a pixel array 1100, a timing controller 1010, a row decoder 1020, and an output circuit 1030. The image sensor 1000 may include a charge coupled device (CCD) image sensor or a complementary metal oxide semiconductor (CMOS) image sensor.

The pixel array 1100 may include pixels which are two-dimensionally arranged along a plurality of rows and columns thereof. The row decoder 1020 may select one row from among the rows of the pixel array 1100 in response to a row address signal output from the timing controller 1010. The output circuit 1030 may output a light sensing signal by column units from a plurality of pixels arranged along the selected row. To this end, the output circuit 1030 may include a column decoder and an analog-to-digital converter (ADC). For example, the output circuit 1030 may include a plurality of ADCs respectively provided in columns between a column decoder and the pixel array 1100, or may include one ADC which is disposed at an output terminal of the column decoder. The timing controller 1010, the row decoder 1020, and the output circuit 1030 may be implemented as one chip or individual chips. A processor for processing an image signal output through the output circuit 1030 may be implemented as one chip along with the timing controller 1010, the row decoder 1020, and the output circuit 1030. The pixel array 1100 may include a plurality of pixels which sense pieces of light having different wavelengths. The arrangement of pixels may be implemented as various types.

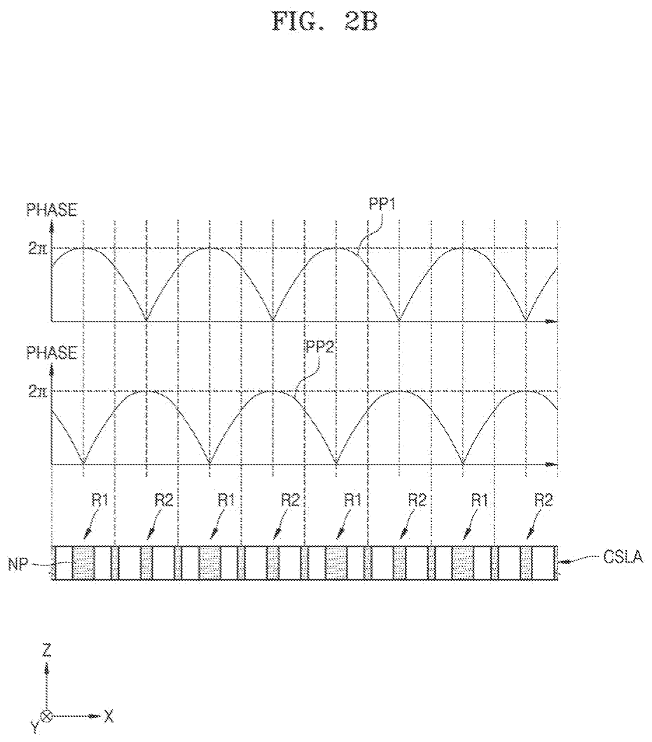

FIGS. 2A and 2B are conceptual diagrams illustrating a structure and an operation of a color separating lens array included in an image sensor according to an embodiment.

Referring to FIG. 2A, a color separating lens array CSLA may include a plurality of nano posts NP which differently change a phase of incident light Li, based on an incident position. The color separating lens array CSLA may be divided in various ways. For example, the color separating lens array CSLA may be divided into a first pixel correspondence region R1, corresponding to a first pixel PX1 on which first wavelength light LA1 included in incident light Li concentrates, and a second pixel correspondence region R2 corresponding to a second pixel PX2 on which second wavelength light LA2 included in the incident light Li concentrates. The first and second pixel correspondence regions R1 and R2 may each include one or more nano posts NP and may be disposed to respectively face the first and second pixels PX1 and PX2. As another example, the color separating lens array CSLA may be divided into a first wavelength concentration region L1 where the first wavelength light LA1 concentrates on the first pixel PX1 and a second wavelength concentration region L2 where the second wavelength light LA2 concentrates on the second pixel PX2. A partial region of the first wavelength concentration region L1 may be overlapped a partial region of the second wavelength concentration region L2.

The color separating lens array CSLA may form different phase profiles in the first and second wavelength light LA1 and LA2 included in the incident light Li, and then, may concentrate the first wavelength light LA1 on the first pixel PX1 and may concentrate the second wavelength light LA2 on the second pixel PX2.

For example, referring to FIG. 2B, the color separating lens array CSLA may respectively concentrate the first and second wavelength light L_{λ1} and L_{λ2} on the first and second pixels PX1 and PX2 so that the first wavelength light L_{λ1} has a first phase profile PP1 and the second wavelength light L_{λ2} has a second phase profile PP2, at a lower surface position of the color separating lens array CSLA that is a position immediately after light passes through the color separating lens array CSLA. For example, the first wavelength light L_{λ1} passing through the color separating lens array CSLA may have a phase profile which is largest at a center of the first pixel correspondence region R1 and decreases in a direction (i.e., a direction toward the second pixel correspondence region R2) away from a center of the first pixel correspondence region R1. Such a phase profile may be similar to a phase profile of light which passes through a convex lens (for example, a micro lens including a center portion which is disposed in the first wavelength concentration region L1 and is convex) and converges to an arbitrary point, and the first wavelength light L_{λ1} may concentrate on the first pixel PX1. Also, the second wavelength light L_{λ2} passing through the color separating lens array CSLA may have a phase profile which is largest at a center of the second pixel correspondence region R2 and decreases in a direction (i.e., a direction toward the first pixel correspondence region R1) away from a center of the second pixel correspondence region R2, and thus, the second wavelength light L_{λ2} may concentrate on the second pixel PX2.

Because a refractive index of a material is differently changed based on a wavelength of light, the color separating lens array CSLA may provide different phase profiles with respect to the first and second wavelength light L_{λ1} and L_{λ2}. For example, despite the same material, because a refractive index is differently changed based on a wavelength of light reacting with a material and the phase delay of light occurring when passing through a material differs for each wavelength, different phase profiles may be formed by wavelengths. For example, a refractive index of the first wavelength light L_{λ1} of the first pixel correspondence region R1 may differ from that of the second wavelength light L_{λ2} of the first pixel correspondence region R1 and the phase delay of the first wavelength light L_{λ1} passing through the first pixel correspondence region R1 may differ from that of the second wavelength light L_{λ2} of the first pixel correspondence region R1. Accordingly, when the color separating lens array CSLA is designed based on such a characteristic of light, the first wavelength light L_{λ1} and the second wavelength light L_{λ2} may be provided to have different phase profiles.

The color separating lens array CSLA may include a nano post NP where the first and second wavelength light L_{λ1} and L_{λ2} are arranged based on a certain rule to have the first and second phase profiles PP1 and PP2. For example, a rule may be applied to parameters such as a shape, a size (a width and a height), an interval, and an arrangement type of the nano post NP, and the parameters may be determined based on a phase profile which is to be implemented through the color separating lens array CSLA.

A rule where a nano post NP is disposed in the first pixel correspondence region R1 may differ from a rule where a nano post NP is disposed in the second pixel correspondence region R2. For example, a size, a shape, an interval, and/or an arrangement type of a nano post NP included in the first pixel correspondence region R1 may differ from a size, a shape, an interval, and/or an arrangement type of a nano post NP included in the second pixel correspondence region R2.

A nano post NP may have a shape dimension of a sub-wavelength. For example, the sub-wavelength denotes a wavelength which is less than a wavelength band of light which is to be separated. The nano post NP may have, for example, a dimension which is less than a shorter wavelength among a first wavelength and a second wavelength. The nano post NP may have a cylindrical shape having a cross-sectional diameter of a sub-wavelength. However, a shape of the nano post NP is not limited thereto. When the incident light Li is visible light, a diameter of a cross-sectional surface of the nano post NP may have, for example, a dimension is about 400 mm, about 300 mm, or less than 200 mm. Furthermore, a height of the nano post NP may be about 500 nm to about 1,500 nm and may be greater than a diameter of a cross-sectional surface tof the nano post NP. The nano post NP may be implemented by a combination of two or more posts which are stacked in a vertical direction (a Z direction).

The nano post NP may include a material having a refractive index which is greater than a refractive index of a peripheral material. For example, the nano post NP may include crystal silicon (c-Si), polysilicon (p-Si), amorphous silicon (a-Si), a III-V compound semiconductor (for example, gallium phosphide (GaP), gallium nitride (GaN), gallium arsenide (GaAs), etc.), silicon carbide (SiC), titanium oxide (TiO₂), silicon nitride (SiN), and/or a combination thereof. The nano post NP having a refractive index that is different from a refractive index of a peripheral material may change a phase of light passing through the nano post NP. This may be based on phase delay which occurs due to a shape dimension of a sub-wavelength, and the degree of delay of a phase may be determined based on a shape, dimension, and arrangement type of the nano post NP. A peripheral material of the nano post NP may include a dielectric material having a refractive index which is less than a refractive index of the nano post NP. For example, the peripheral material may include silicon oxide (SiO₂) or air. However, embodiments are not limited thereto, and properties of the nano post NP and the peripheral material of the nano post NP may be set so that the nano post NP has a refractive index which is less than a refractive index of the peripheral material.

Region division of the color separating lens array CSLA and the shapes and arrangement of nano posts NP may be set so that incident light is separated based on a wavelength to form a phase profile allowing separated pieces of light to concentrate on the plurality of pixels PX1 and PX2. Such wavelength separation may include color separation of a visible light band, but embodiments are not limited thereto and a wavelength band may extend to a visible light range, an infrared range, or other various ranges. A first wavelength λ₁ and a second wavelength λ₂ may have an infrared wavelength band to a visible wavelength band, but are not limited thereto and may have various wavelength bands, based on an arrangement rule of an array of a plurality of nano posts NP. An example where two wavelengths branch and concentrate is described, but incident light may branch in three or more directions and concentrate, based on a wavelength.

Moreover, a case where nano posts NP are arranged as a single layer has been described as an example of the color separating lens array CSLA. However, embodiments are not limited thereto, and the color separating lens array CSLA may have a stack structure where nano posts NP are arranged as a plurality of layers.

Furthermore, as described above, wavelength separation by the color separating lens array CSLA may be based on a refractive index profile based on the shapes and properties of a nano post NP and a peripheral material of the nano post NP, and in a case where parameters for forming a desired refractive index profile are not well implemented due to a process error, efficiency may be reduced. The image sensor according to an embodiment may be manufactured by a manufacturing method for decreasing process scattering in a manufacturing process, and thus, color separation efficiency may be maximized.

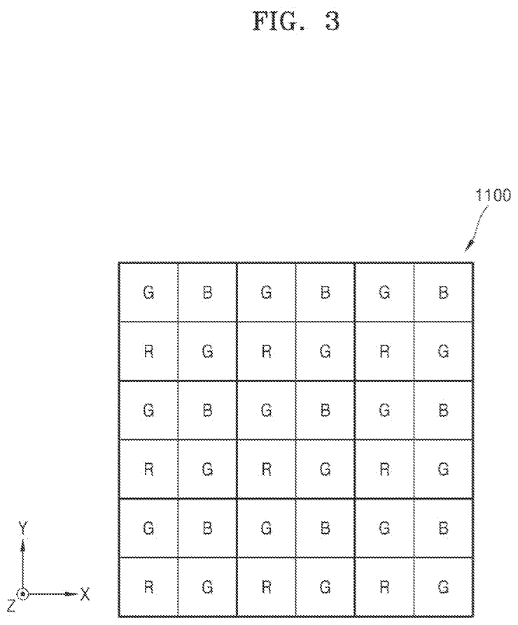

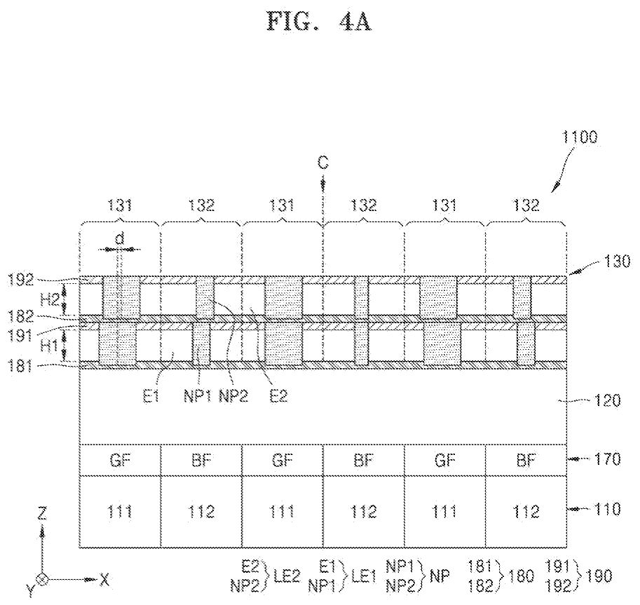

FIG. 3 is a plan view illustrating color arrangement in a pixel array of an image sensor 1000 according to an embodiment.

Referring to FIGS. 2A to 3, the illustrated pixel arrangement may be an arrangement of a Bayer pattern which is generally used in the image sensor 1000. As illustrated, one unit pixel may include four quadrant regions, and first to fourth quadrant surfaces may respectively be a blue pixel B, a green pixel G, a red pixel R, and a green pixel G. Such a unit pattern may be two-dimensionally and repeatedly arranged in a first horizontal direction (an X direction) and a second horizontal direction (a Y direction). For example, two green pixels G may be arranged in one diagonal direction in a unit pattern of a 2×2 array type, and one blue pixel B and one red pixel R may be arranged in the other diagonal direction. Referring to the whole pixel arrangement, a first row where a plurality of green pixels G and a plurality of blue pixels B are alternately arranged in the first horizontal direction (the X direction) and a second row where a plurality of red pixels R and a plurality of green pixels G are alternately arranged in the second horizontal direction (the Y direction) may be repeatedly arranged.

A pixel array 1100 of the image sensor 1000 may include the color separating lens array CSLA which concentrates light, having a color corresponding to a certain pixel, on the certain pixel to correspond to the color arrangement. For example, region division and the shape and arrangement of nano posts NP may be set so that separated wavelengths in the color separating lens array CSLA described above with reference to FIGS. 2A and 2B are a red wavelength, a green wavelength, and/or a blue wavelength.

The color arrangement of FIG. 3 only an example and embodiments are not limited thereto. For example, a CYGM-type array where a magenta pixel M, a cyan pixel Cy, a yellow pixel Y, and a green pixel G configure one unit pattern may be used, or an RGBW-type array where a green pixel G, a red pixel R, a blue pixel B, and a white pixel W configure one unit pattern may be used. Also, a unit pattern may be implemented as a 3×2 array type, and in addition, pixels of the pixel array 1100 may be arranged as various types based on a color characteristic of the image sensor 1000. Hereinafter, an example where the pixel array 1100 of the image sensor 1000 has a Bayer pattern is described, but an operation principle may be applied to another type of pixel array instead of the Bayer pattern.

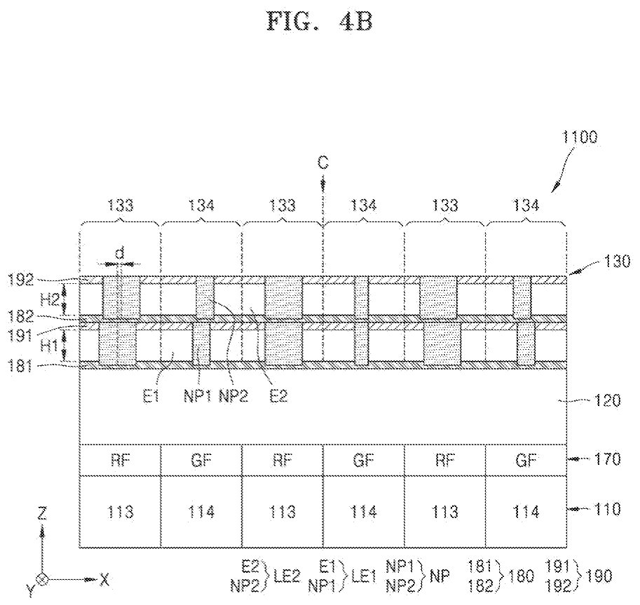

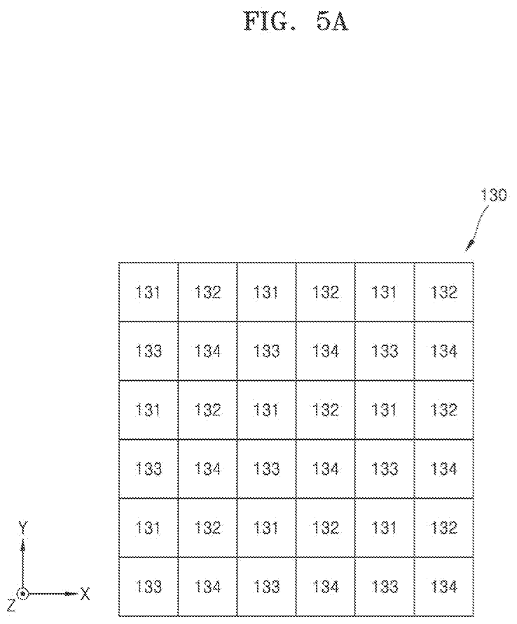

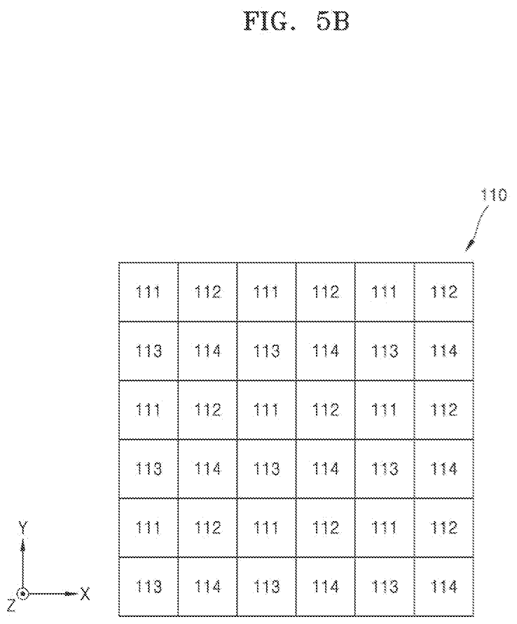

FIGS. 4A and 4B are cross-sectional views illustrating different cross-sectional surfaces of the pixel array 1100 of the image sensor 1000 of FIG. 1. FIG. 5A is a plan view illustrating an arrangement of a pixel correspondence region of a color separating lens array included in a pixel array, and FIG. 5B is a plan view illustrating a pixel arrangement of a sensor substrate included in a pixel array.

Referring to FIGS. 4A and 4B, a pixel array 1100 of the image sensor 1000 may include a sensor substrate 110 which includes a first green pixel 111, a blue pixel 112, a red pixel 113, and a second green pixel 114 sensing light and a color separating lens array 130 which is disposed on the sensor substrate 110.

The sensor substrate 110 may include a plurality of light sensing cells which sense light and convert the sensed light into an electrical signal. The plurality of light sensing cells may include the first green pixel 111, the blue pixel 112, the red pixel 113, and the second green pixel 114. As illustrated in FIGS. 4A, 4B, and 5D, the first green pixel 111 and the blue pixel 112 may be alternately arranged in a first horizontal direction (an X direction), and the red pixel 113 and the second green pixel 114 may be alternately arranged on a cross-sectional surface at a different position in a second horizontal direction (a Y direction).

Herein, a direction parallel to a main surface of the sensor substrate 110 may be referred to as a horizontal direction (the X direction and/or the Y direction), and a direction perpendicular to the horizontal direction (the X direction and/or the Y direction) may be referred to as a vertical direction (a Z direction).

A spacer layer 120 may be disposed between the sensor substrate 110 and the color separating lens array 130 and may intactly maintain an interval between the sensor substrate 110 and the color separating lens array 130. The spacer layer 120 may include a transparent material with respect to visible light, and for example, may include a dielectric material which has a relatively low absorption rate in a visible band and has a refractive index which is less than a refractive index of a nano post NP such as SiO₂ or siloxane-based spin on glass (SOG). A thickness h of the spacer layer 120 may be selected within a range of ht−p≤h≤ht+p. Here, ht may denote a focus distance of light having a center wavelength of a wavelength band where the color separating lens array 130 branches, and p may denote a pixel pitch. In an embodiment, the pixel pitch may be several μm or less, and for example, may be about 2 μm or less, about 1.5 μm or less, about 1 μm or less, or about 0.7 μm or less. The pixel pitch may be within a range of about 0.5 μm to about 1.5 μm. A thickness of the spacer layer 120 may be designed based on, for example, about 540 nm which is a center wavelength of green light.

The spacer layer 120 may support a nano post NP which configures the color separating lens array 130. The spacer layer 120 may include a dielectric material having a refractive index which is less than that of a first nano post NP1. When a first peripheral material layer E1 includes a material having a refractive index which is less than a refractive index of the first nano post NP1, the spacer layer 120 may include a material having a refractive index which is less than that of the first peripheral material layer E1.

The color separating lens array 130 may be a type where a plurality of nano posts NP are arranged as a plurality of layers. The color separating lens array 130 may include a first lens layer LE1 and a second lens layer LE2. The first lens layer LE1 may include a plurality of first nano posts NP1 and a first peripheral material layer E1 disposed at peripheries thereof, and the second lens layer LE2 may include a plurality of second nano posts NP2 and a second peripheral material layer E2 disposed at peripheries thereof. The first peripheral material layer E1 may be disposed adjacent to and to surround a side surface of the first nano post NP1, and the second peripheral material layer E2 may be disposed adjacent to and to surround a side surface of the second nano post NP2. The first nano post NP1 may include a material which is greater in refractive index than the first peripheral material layer E1, and the second nano post NP2 may include a material which is greater in refractive index than the second peripheral material layer E2. However, embodiments are not limited thereto, and a refractive index relationship may be opposite thereto.

The color separating lens array 130 may be divided into four pixel correspondence regions 131 to 134 respectively corresponding to the pixels 111 to 114 of the sensor substrate 110. The first green pixel correspondence region 131 may be disposed on the first green pixel 111 to correspond to the first green pixel 111, the blue pixel correspondence region 132 may be disposed on the blue pixel 112 to correspond to the blue pixel 112, the red pixel correspondence region 133 may be disposed on the red pixel 113 to correspond to the red pixel 113, and the second green pixel correspondence region 134 may be disposed on the second green pixel 114 to correspond to the second green pixel 114. For example, the pixel correspondence regions 131 to 134 of the color separating lens array 130 may be disposed to respectively face the a first green pixel 111, a blue pixel 112, a red pixel 113, and a second green pixel 114 of the sensor substrate 110. The pixel correspondence regions 131 to 134 may be two-dimensionally arranged in the first horizontal direction (the X direction) and the second horizontal direction (the Y direction) so that a first row where the first green pixel correspondence region 131 and the blue pixel correspondence region 132 are alternately arranged and a second row where the red pixel correspondence region 133 and the second green pixel correspondence region 134 are alternately arranged are alternately repeated. The color separating lens array 130 may include a plurality of unit patterns which are two-dimensionally arranged similar to the sensor substrate 110, and each of the plurality of unit patterns may include the pixel correspondence regions 131 to 134 which are arranged as a 2×2 type.

Furthermore, similar to the description of FIG. 2A in concept, a region of the color separating lens array 130 may be described as including a green light concentration region on which green light concentrates, a blue light concentration region on which blue light concentrates, and a red light concentration region on which red light concentrates.

The color separating lens array 130 may include first and second nano posts NP1 and NP2 where a size, a shape, an interval, and/or arrangement are determined, so that green light branches to and concentrates on the first and second green pixels 111 and 114, blue light branches to and concentrates on the blue pixel 112, and red light branches to and concentrates on the red pixel 113.

A material having a high refractive index among the first nano post NP1, the second nano post NP2, the first peripheral material layer E1, and the second peripheral material layer E2 may include at least one of c-Si, p-Si, a-Si, a III-V compound semiconductor (for example, GaP, GaN, GaAs, etc.), SiC, TiO₂, and SiN, and a material having a low refractive index may include a polymer material such as SU-8 or poly(methylmethacrylate) (PMMA), SiO₂, SOG, or air.

Each of the first nano post NP1 and the second nano post NP2 may have a post shape which has a height in a vertical direction (a Z direction), or may have a circular pillar shape, an oval pillar shape, or a polygonal pillar shape or may have a post shape having a symmetrical or asymmetrical cross-sectional shape. Each of the first nano post NP1 and the second nano post NP2 is illustrated so that a width vertical to a height direction thereof is constant (i.e., a cross-sectional surface parallel to the height direction thereof has a rectangular shape), but embodiments are not limited thereto. For example, in each of the first nano post NP1 and the second nano post NP2, the width vertical to the height direction thereof may not be constant, and for example, a shape of the cross-sectional surface parallel to the height direction thereof may be a reversed trapezoidal shape.

Also, the first nano post NP1 and the second nano post NP2 overlapping each other in the vertical direction (the Z direction) may not be connected with each other and may be spaced apart from each other. An etch stop layer 180 may be disposed between the first nano post NP1 and the second nano post NP2.

A height of each of the first nano post NP1 and the second nano post NP2 may be several times a sub-wavelength or a wavelength. For example, the height of each of the first nano post NP1 and the second nano post NP2 may be equal to or greater than half of a center wavelength of a wavelength band where the color separating lens array 130 branches and may be equal to or less than about 5 times the center wavelength, about 4 times the center wavelength, or about 3 times the center wavelength. The height of each of the first nano post NP1 and the second nano post NP2 may be, for example, about 500 nm to about 1,500 nm.

The first nano post NP1 and the second nano post NP2 may be disposed between the first lens layer LE1 and the second lens layer LE2 to correspond to each other and may be disposed so that a center axis of the first nano post NP1 and a center axis of the second nano post NP2 are disposed to be staggered without matching therebetween. A horizontal distance d between two center axes of each of the first nano post NP1 and the center axis of the second nano post NP2 may be equal to or greater than 0. For example, two center axes of each of the first nano post NP1 and the second nano post NP2 at an arbitrary position may be aligned in the vertical direction (the Z direction), and two center axes of each of the first nano post NP1 and the second nano post NP2 at a different position may not be aligned in the vertical direction (the Z direction). A horizontal separation distance between two center axes may increase in a direction away from a center C of the pixel array 1100 in a horizontal direction (the X direction and/or the Y direction). A separated direction between the two center axes of the first nano post NP1 and a separated direction between the two center axes of the second nano post NP2 may be opposite to each other with respect to the center C of the pixel array 1100. The second nano post NP2 may be shifted toward the center C of the color separating lens array 130 (i.e., toward the left) rather than the first nano post NP1 at a position corresponding thereto, in a right region with respect to the center C of the color separating lens array 130. The second nano post NP2 may be shifted toward the center C of the color separating lens array 130 (i.e., toward the right) rather than the first nano post NP1 at a position corresponding thereto, in a left region with respect to the center C of the color separating lens array 130. As described above, the arrangement of the first nano post NP1 and the second nano post NP2 may be based on that an angle of a chief ray differs for each position of the color separating lens array 130. The amount of shift may be proportional to a distance to the center C of the color separating lens array 130. For example, a separation distance between the two center axes of each of the first and second nano posts NP1 and NP2 which are adjacent to each other and have a correspondence relationship in two layers may increase in a direction away from the center C of the color separating lens array 130.

A color filter array 170 may be disposed between the sensor substrate 110 and the color separating lens array 130. The color filter array 170 may include a red filter RF, a green filter GF, and a blue filter BF and may be arranged as a type corresponding to the color arrangement as illustrated in FIG. 3. For example, the color separating lens array 130 may perform color separation, and the color filter array 170 additionally provided may complement a certain error occurring in color separation by the color separating lens array 130, thereby increasing color purity. In another embodiment, the color filter array 170 may be omitted. For example, a thickness of the spacer layer 120 may be set to be less than a focus distance, which is based on the color separating lens array 130, of light having a center wavelength of a wavelength band separated by the color separating lens array 130. For example, the thickness of the spacer layer 120 may be set to be less than a focus distance of green light based on the color separating lens array 130.

A first etch stop layer 181 may be disposed between the first peripheral material layer E1 and the spacer layer 120, and a second etch stop layer 182 may be disposed between the first peripheral material layer E1 and the second peripheral material layer E2. For example, the second etch stop layer 182 may be disposed on a first chemical mechanical polishing (CMP) stop layer 191 and the first nano post NP1. The first etch stop layer 181 may be disposed between the first peripheral material layer E1 and the spacer layer 120 so that the spacer layer 120 is not damaged by a process of forming the first lens layer LE1, and a second etch stop layer 182 may be disposed between the first lens layer LE1 and the second lens layer LE2 so that the first lens layer LE1 is not damaged by a process of forming the second lens layer LE2. For example, the first and second etch stop layers 181 and 182 may include hafnium oxide (HfO₂), SiO₂, and/or aluminum oxide (AlO) and may be formed all over a total area of the color separating lens array 130. The first and second etch stop layers 181 and 182 may have a thickness which enables a lower layer protection function to be performed without damaging an optical characteristic of the color separating lens array 130, and a thickness of each of the first and second etch stop layers 181 and 182 may be, for example, about 1 nm to about 30 nm.

According to an embodiment, a vertical level of a lowermost surface of the first nano post NP1 may be lower than a vertical level of an uppermost surface of the first etch stop layer 181, and a vertical level of a lowermost surface of the second nano post NP2 may be lower than a vertical level of an uppermost surface of the second etch stop layer 182. For example, the first nano post NP1 may be formed to penetrate at least a portion of the first etch stop layer 181, and the second nano post NP2 may be formed to penetrate at least a portion of the second etch stop layer 182. An upper surface of the first etch stop layer 181 and an upper surface of the second etch stop layer 182 may have a concave-convex portion.

The first CMP stop layer 191 may be formed on the entire surface, except the upper surface of the first nano post NP1, between the first lens layer LE1 and the second lens layer LE2. For example, the first CMP stop layer 191 may not be disposed on the upper surface of the first nano post NP1 and may be disposed to directly contact only an upper surface of the first peripheral material layer E1. An upper surface of the first CMP stop layer 191 and the upper surface of the first nano post NP1 may be connected with each other and may be coplanar. For example, the upper surface of the first CMP stop layer 191 and the upper surface of the first nano post NP1 may be disposed at the same vertical level. Also, a second CMP stop layer 192 may be formed on the entire surface, except the upper surface of the second nano post NP2, on the second lens layer LE2. For example, the second CMP stop layer 192 may not be disposed on the upper surface of the second nano post NP2 and may be disposed to directly contact only an upper surface of the second peripheral material layer E2. An upper surface of the second CMP stop layer 192 and the upper surface of the second nano post NP2 may be connected with each other and may be coplanar. For example, the upper surface of the second CMP stop layer 192 and the upper surface of the second nano post NP2 may be disposed at the same vertical level.

The first CMP stop layer 191 and the second CMP stop layer 192 may be elements which are provided so that a height of each of the first lens layer LE1 and the second lens layer LE2 is implemented in a desired shape, in a process of manufacturing the first lens layer LE1 and the second lens layer LE2. For example, in order to manufacture a pattern including a material having a high refractive index and a material having a low refractive index, a process of forming an engraved pattern in a low refractive index material layer, filling a material having a high refractive index into the engraved pattern, and planarizing the engraved pattern may be used. In this case, scattering may occur in a CMP process which is performed. Also, as the amount of removal by CMP increases, process scattering may increase in proportion thereto. To decrease the process scattering, the first etch stop layer 181, the second etch stop layer 182, the first CMP stop layer 191, and the second CMP stop layer 192 may be included in each operation of manufacturing the first lens layer LE1 and the second lens layer LE2, and this will be described in more detail in describing a manufacturing method.

A material and a thickness of each of the first CMP stop layer 191 and the second CMP stop layer 192 may be determined based on a material and a thickness of each of the first nano post NP1 and the second nano post NP2 and a CMP selectivity difference with the material of each of the first nano post NP1 and the second nano post NP2. For example, compared to the material of each of the first nano post NP1 and the second nano post NP2, each of the first CMP stop layer 191 and the second CMP stop layer 192 may include a material where a CMP selectivity is low, so as not to be removed in a CMP process. Each of the first CMP stop layer 191 and the second CMP stop layer 192 may include, for example, aluminum oxide (Al₂O₃), SiN, silicon carbon-nitride (SiCN), and/or HfO₂. For example, a range of a thickness of each of the first CMP stop layer 191 and the second CMP stop layer 192 may be about 1 nm to about 100 nm.

The pixel arrangement of the sensor substrate 110 illustrated in FIG. 5B may be the arrangement of pixels corresponding to the color arrangement of the Bayer pattern illustrated in FIG. 3. Hereinafter, the pixel arrangement of an image sensor and the pixel arrangement of the sensor substrate 110 may be the same and may be interchangeably used. The pixel arrangement of the sensor substrate 110 may be configured to divide and sense incident light, based on a unit pattern such as the Bayer pattern, and for example, the first and second green pixels 111 and 114 may sense green light, the blue pixel 112 may sense blue light, and the red pixel 113 may sense red light. A separation layer configured to separate cells may be further formed at a boundary between cells.

In a plan view of FIG. 5A, nano posts NP may be arranged as various types in each of the pixel correspondence regions 131 to 134. In FIG. 5A, the illustration of shapes of nano posts NP is omitted. The shapes and arrangement of nano posts NP illustrated in the cross-sectional views of FIGS. 4A and 4B are only examples, and embodiments are not limited thereto. In FIGS. 4A and 4B, it is illustrated that one first nano post NP1 and one second nano post NP2 are included in each region, but embodiments are not limited thereto. The number of first nano posts NP1 included in each region may differ from the number of second nano posts NP2 included in each region, and the second nano post NP2 corresponding to the first nano post NP1 may not be provided at an arbitrary position. The first nano post NP1 and the second nano post NP2 may be disposed at a boundary between regions.

A pixel arrangement feature of the Bayer pattern may be reflected in the arrangement of nano posts NP in the pixel correspondence regions 131 to 134. In the Bayer pattern pixel arrangement, pixels adjacent to the blue pixel 112 and the red pixel 113 in the first horizontal direction (the X direction) and the second horizontal direction (the Y direction) may be the same green pixels, a pixel adjacent to the first green pixel 111 in the first horizontal direction (the X direction) may be the blue pixel 112, a pixel adjacent to the first green pixel 111 in the second horizontal direction (the Y direction) may be the red pixel 113 which differs from the pixel adjacent to the first green pixel 111 in the first horizontal direction (the X direction), a pixel adjacent to the second green pixel 114 in the first horizontal direction (the X direction) may be the red pixel 113, and a pixel adjacent to the second green pixel 114 in the second horizontal direction (the Y direction) may be the blue pixel 112 which differs from the pixel adjacent to the second green pixel 114 in the first horizontal direction (the X direction). Also, pixels adjacent to the first and second green pixels 111 and 114 in four diagonal directions may be green pixels, pixels adjacent to the blue pixel 112 in four diagonal directions may be the same red pixels 113, and pixels adjacent to the red pixel 113 in four diagonal directions may be the same blue pixels 112. Therefore, first nano posts NP1 may be arranged in a 4-fold symmetry shape in the blue and red pixel correspondence regions 132 and 133, and first nano posts NP1 may be arranged in a 2-fold symmetry shape in the first and second green pixel correspondence regions 131 and 134. The first nano posts NP1 of the first and second green pixel correspondence regions 131 and 134 may have an asymmetrical cross-sectional shape where a width in the first horizontal direction (the X direction) differs from a width in the second horizontal direction (the Y direction), and the first nano posts NP1 of the blue and red pixel correspondence regions 132 and 133 may have a symmetrical cross-sectional shape where a width in the first horizontal direction (the X direction) is the same as a width in the second horizontal direction (the Y direction). The first nano posts NP1 arrangement of the first and second green pixel correspondence regions 131 and 134 may be in a 90-degree rotated form with respect to one another.

The second nano posts NP2 of the second lens layer LE2 may be set based on a shift condition described above in a relationship with the first nano post NP1. In general image sensors, an arrangement rule of the first nano post NP1 and the second nano post NP2 may be an embodiment for wavelength separation corresponding to pixel arrangement, but the patterns described above or illustrated are not limited thereto.

In the general image sensors, an etch stop layer and a CMP stop layer may not be disposed between a first lens layer and a second lens layer, and due to this, scattering of a vertical-direction height of a nano post may be relatively large.

On the other hand, in the pixel array 1100 according to an embodiment, the etch stop layer 180 may be disposed between the first peripheral material layer E1 and the second peripheral material layer E2, and thus, the degree of etching of the second peripheral material layer E2 may be more precisely adjusted. Also, in the pixel array 1100 according to an embodiment, the CMP stop layer 190 may be disposed between the first peripheral material layer E1 and the second peripheral material layer E2, and thus, a height of an upper surface of the nano post NP may be more easily adjusted. Accordingly, the pixel array 1100 according to an embodiment may relatively decrease scattering of a vertical-direction height of each of a plurality of nano posts NP.

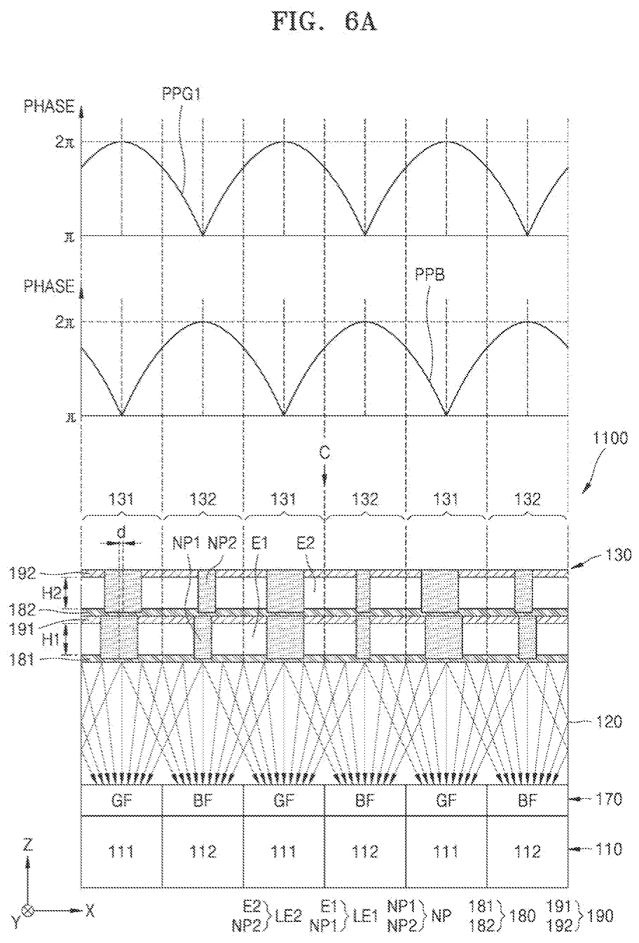

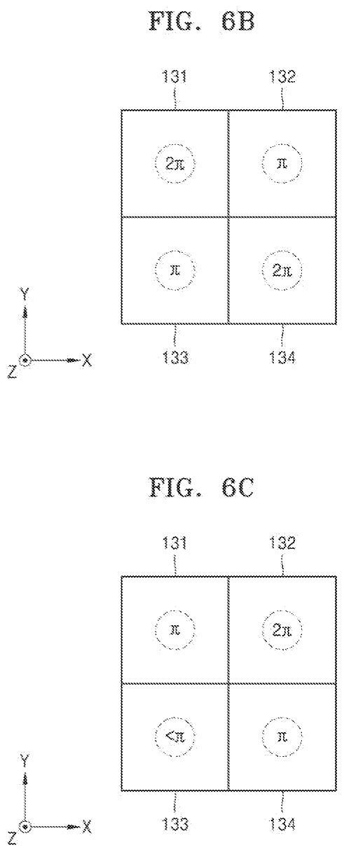

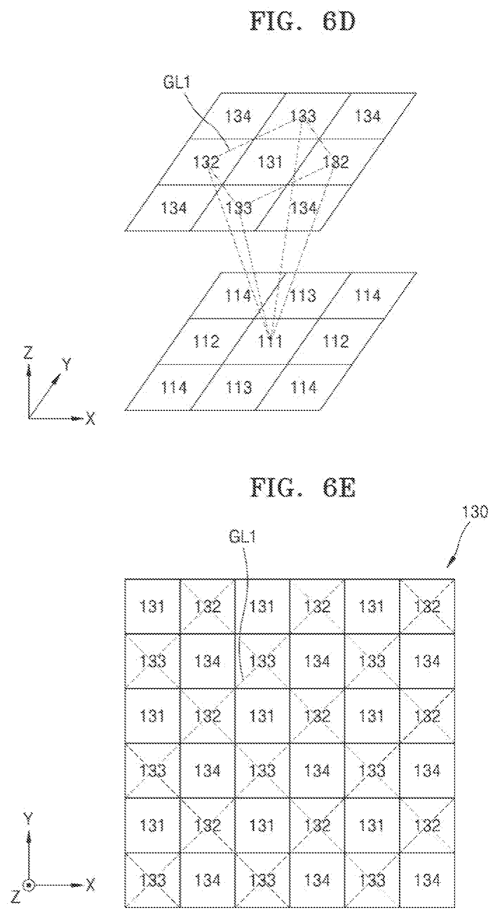

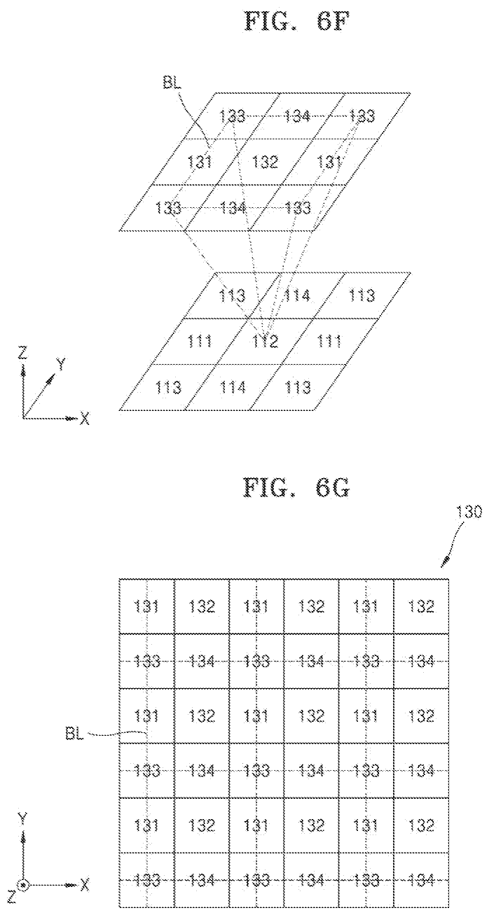

FIG. 6A shows phase profiles of green light and blue light passing through a color separating lens array in terms of the cross-sectional surface of FIG. 4A, FIG. 6B shows a phase at a center of pixel correspondence regions of green light passing through a color separating lens array, and FIG. 6C shows a phase at a center of pixel correspondence regions of blue light passing through a color separating lens array. The phase profiles of the green light and the blue light of FIG. 6A may be similar to phase profiles of first and second wavelength light described above with reference to FIG. 2B.

Referring to FIGS. 6A and 6B, green light passing through a color separating lens array 130 may be largest at a center of a first green pixel correspondence region 131 and may have a first green light phase profile PPG1 which decreases progressively in a direction away from the center of the first green pixel correspondence region 131. For example, at a position immediately after passing through the color separating lens array 130 (i.e., at a lower surface of the color separating lens array 130 or an upper surface of a spacer layer 120), a phase of green light may be largest at a center of the first green pixel correspondence region 131 and may decrease progressively in a concentric shape in a direction away from the center of the first green pixel correspondence region 131, and thus, may be the minimum at centers of blue and red pixel correspondence regions 132 and 133 in a first horizontal direction (an X direction) and a second horizontal direction (a Y direction) and may be the minimum at a contact point between the first green pixel correspondence region 131 and a second green pixel correspondence region 134 in a diagonal direction. When it is assumed that a phase of light emitted at a center of the first green pixel correspondence region 131 of green light is 2π, light may be emitted where a phase at each of the centers of the blue and red pixel correspondence regions 132 and 133 is about 0.9π to about 1.1π, a phase at a center of the second green pixel correspondence region 134 is about 2π, and a phase at the contact point between the first green pixel correspondence region 131 and the second green pixel correspondence region 134 is about 1.1π to about 1.5π. Accordingly, a phase difference between green light passing through the center of the first green pixel correspondence region 131 and green light passing through the centers of the blue and red pixel correspondence regions 132 and 133 may be about 0.9π to about 1.1π.

Furthermore, the first green light phase profile PPG1 may not denote that the amount of phase delay of light passing through the center of the first green pixel correspondence region 131 is largest, and in a case where it is assumed that a phase of light passing through the first green pixel correspondence region 131 is 2π, the first green light phase profile PPG1 may denote a value (i.e., a profile of a wrapped phase) remaining after removal of about 2nπ when the phase delay of light passing through a different position is larger and has a phase value which is greater than 2π. For example, in a case where it is assumed that a phase of light passing through the first green pixel correspondence region 131 is 2π, when a phase of light passing through the center of the blue pixel correspondence region 132 is about 3π, a phase of the blue pixel correspondence region 132 may be π remaining after 2π (n=1) is removed from 3π.

Referring to FIGS. 6A and 6C, blue light passing through the color separating lens array 130 may be largest at a center of a blue pixel correspondence region 132 and may have a blue light phase profile PPB which decreases progressively in a direction away from the center of the blue pixel correspondence region 132. For example, at a position immediately after passing through the color separating lens array 130, a phase of blue light may be largest at the center of the blue pixel correspondence region 132 and may decrease progressively in a concentric shape in a direction away from the center of the blue pixel correspondence region 132, and thus, may be the minimum at centers of first and second green pixel correspondence regions 131 and 134 in an X direction and a Y direction and may be the minimum at a center of a red pixel correspondence region 133 in a diagonal direction. When it is assumed that a phase at a center of the blue pixel correspondence region 132 of blue light is 2π, a phase at each of centers of the first and second green pixel correspondence regions 131 and 134 is, for example, about 0.9π to about 1.1π, and a phase at a center of the red pixel correspondence region 133 may have a value (for example, 0.5π to 0.9π) which is less than that of a phase at each of the centers of the first and second green pixel correspondence regions 131 and 134.

FIG. 6D shows a traveling direction of green light incident on a first green light collection region, and FIG. 6E shows an array of the first green light collection region.

Referring to FIGS. 6D and 6E, green light incident on a periphery of a first green pixel correspondence region 131 may concentrate on a first green pixel 111 by using a color separating lens array 130 as illustrated in FIG. 6D, and green light from blue and red pixel correspondence regions 132 and 133 as well as the first green pixel correspondence region 131 may be incident on the first green pixel 111. For example, in the phase profile of the green light described above with reference to FIGS. 6A and 6B, green light, passing through a first green light concentration region GL1 connecting centers of two red pixel correspondence regions 133 with two blue pixel correspondence regions 132 which each include one side contacting the first green pixel correspondence region 131 and is adjacent to the first green pixel correspondence region 131, may concentrate on the first green pixel 111. Accordingly, as illustrated in FIG. 6E, the color separating lens array 130 may operate as a first green light concentration region GL1 array where green light concentrates on the first green pixel 111. An area of the first green light concentration region GL1 may be greater than an area of a corresponding first green pixel 111, and for example, may be 1.2 to 2 times greater than an area of the corresponding first green pixel 111.

FIG. 6F shows a traveling direction of blue light incident on a blue light collection region, and FIG. 6G shows an array of the blue light collection region.

Referring to FIGS. 6F and 6G, blue light may concentrate on a blue pixel 112 by using the color separating lens array 130, and blue light from pixel correspondence regions 131 to 134 may be incident on the blue pixel 112. In the phase profile of the blue light described above with reference to FIGS. 6A and 6C, blue light, passing through a blue light concentration region BL connecting centers of four red pixel correspondence regions 133 with a blue pixel correspondence region 132 which includes a vertex contacting the blue pixel correspondence region 132 and is adjacent to the blue pixel correspondence region 132, may concentrate on the blue pixel 112. Accordingly, the color separating lens array 130 may operate as a blue light concentration region BL array where blue light concentrates on the blue pixel 112. An area of the blue light concentration region BL may be greater than an area of a corresponding blue pixel 112, and for example, may be 1.5 to 4 times greater than an area of the corresponding blue pixel 112. A partial region of the blue light concentration region BL may overlap the first green light concentration region GL1 described above and a second green light concentration region GL2 and a red light concentration region RL, which will be described below.

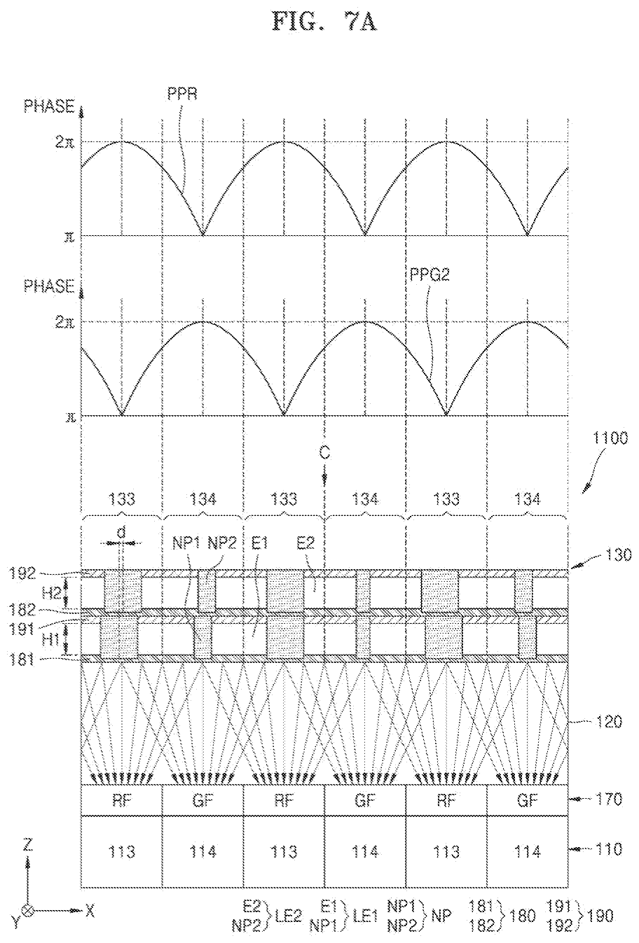

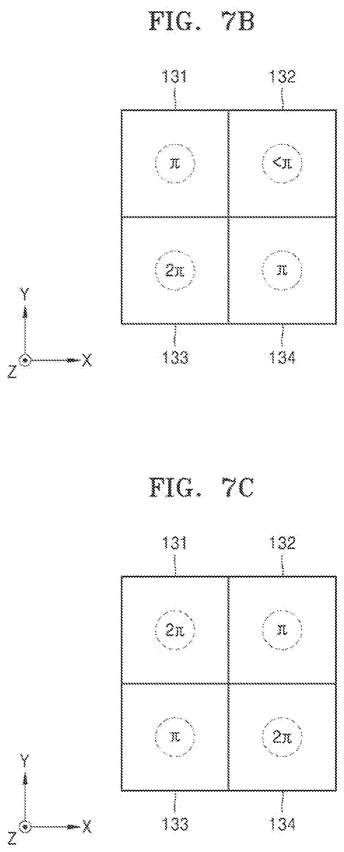

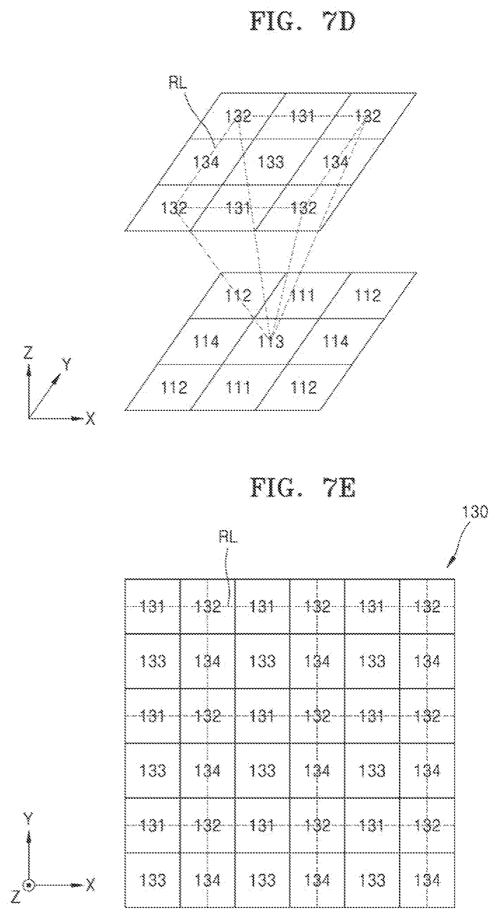

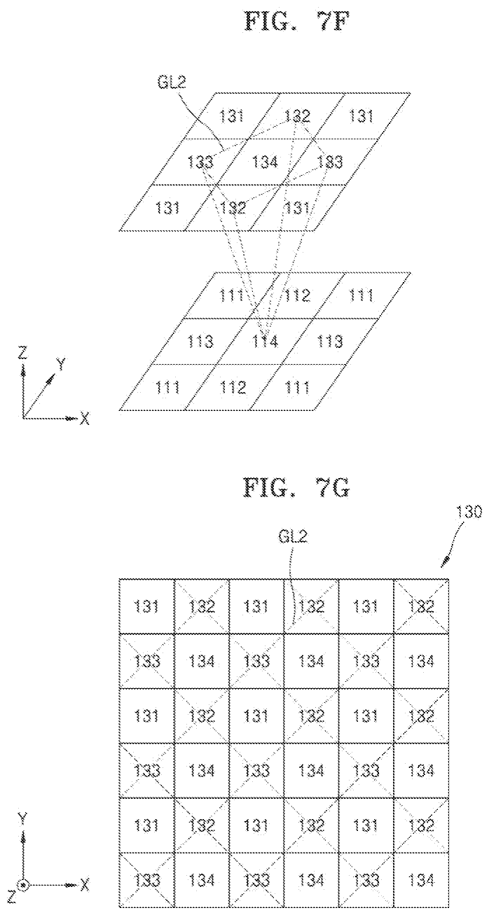

FIG. 7A shows phase profiles of red light and green light passing through a color separating lens array, FIG. 7B shows a phase at a center of pixel correspondence regions of red light passing through a color separating lens array, and FIG. 7C shows a phase at a center of pixel correspondence regions of green light passing through a color separating lens array.

Referring to FIGS. 7A and 7B, red light passing through a color separating lens array 130 may be largest at a center of a red pixel correspondence region 133 and may have a red light phase profile PPR which decreases progressively in a direction away from the center of the red pixel correspondence region 133. For example, at a position immediately after passing through the color separating lens array 130, a phase of red light may be largest at the center of the red pixel correspondence region 133 and may decrease progressively in a concentric shape in a direction away from the center of the red pixel correspondence region 133, and thus, may be the minimum at centers of first and second green pixel correspondence regions 131 and 134 in an X direction and a Y direction and may be the minimum at a center of a blue pixel correspondence region 132 in a diagonal direction. When it is assumed that a phase at a center of the red pixel correspondence region 133 of red light is 2π, a phase at each of centers of the first and second green pixel correspondence regions 131 and 134 is, for example, about 0.9π to about 1.1π, and a phase at a center of the blue pixel correspondence region 132 may have a value (for example, 0.6π to 0.9π) which is less than that of a phase at each of the centers of the first and second green pixel correspondence regions 131 and 134.

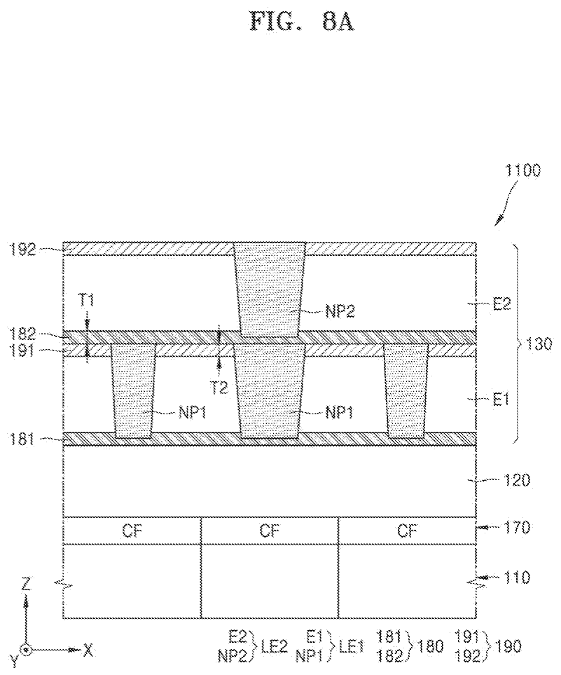

Referring to FIGS. 7A and 7C, green light passing through a color separating lens array 130 may be largest at a center of a second green pixel correspondence region 134 and may have a second green light phase profile PPG2 which decreases progressively in a direction away from the center of the second green pixel correspondence region 134. Comparing the second green light phase profile PPG2 of FIG. 7A with the first green light phase profile PPG1 of FIG. 6A, the second green light phase profile PPG2 may be a phase profile obtained by shifting the first green light phase profile PPG1 by a 1 pixel pitch in an X direction and a Y direction in parallel. For example, in the first green light phase profile PPG1, a phase may be largest at a center of a first green pixel correspondence region 131, and in the second green light phase profile PPG2, a phase may be largest at the center of the second green pixel correspondence region 134 which is spaced apart from the center of the first green light phase profile PPG1 by a 1 pixel pitch in the X direction and the Y direction. Phase profiles of FIGS. 6B and 8C showing phases at centers of pixel correspondence regions 131 to 134 may be the same. To additionally describe a phase profile of green light with respect to the second green pixel correspondence region 134, when it is assumed that a phase of light emitted at a center of the second green pixel correspondence region 134 of green light is 2π, light may be emitted where a phase at each of the centers of the blue and red pixel correspondence regions 132 and 133 is about 0.9π to about 1.1π, a phase at a center of the first green pixel correspondence region 131 is about 2π, and a phase at a contact point between the first green pixel correspondence region 131 and the second green pixel correspondence region 134 is about 1.1π to about 1.5π.

FIG. 7D shows a traveling direction of red light incident on a red light collection region, and FIG. 7E shows an array of the red light collection region.

Referring to FIGS. 7D and 7E, red light may concentrate on a red pixel 113 by using the color separating lens array 130, and red light from pixel correspondence regions 131 to 134 may be incident on the red pixel 113. In the phase profile of the red light described above with reference to FIGS. 7A and 7B, red light, passing through a red light concentration region RL connecting centers of four blue pixel correspondence regions 132 which each include a vertex contacting the red pixel correspondence region 133 and are adjacent to the red pixel correspondence region 133, may concentrate on the red pixel 113. Accordingly, the color separating lens array 130 may operate as a red light concentration region RL array where red light concentrates on the red pixel 113. An area of the red light concentration region RL may be greater than an area of a corresponding red pixel 113, and for example, may be 1.5 to 4 times greater than an area of the corresponding red pixel 113. A partial region of the red light concentration region RL may overlap the first and second green light concentration regions GL1 and GL2 and the blue light concentration region BL.

FIG. 7F shows a traveling direction of green light incident on a second green light collection region, and FIG. 7G shows an array of the second green light collection region.

Referring to FIGS. 7F and 7G, similar to the description of green light incident on a periphery of a first green pixel correspondence region 131, green light incident on a periphery of a second green pixel correspondence region 134 may concentrate on a second green pixel 114. Accordingly, the color separating lens array 130 may operate as a second green light concentration region GL2 array where green light concentrates on the second green pixel 114. An area of the second green light concentration region GL2 may be greater than an area of a corresponding second green pixel 114, and for example, may be 1.2 to 2 times greater than an area of the corresponding second green pixel 114.

FIGS. 8A and 8B are cross-sectional views illustrating a pixel array of an image sensor according to an embodiment and an example where color separating lens arrays are seen at different positions. FIGS. 8A and 8B illustrate shapes of a first nano post NP1 and a second nano post NP2 included in a first lens layer LE1 and a second lens layer LE2 at different positions of a color separating lens array 130. For convenience of illustration, a pixel array 1100 is illustrated as including two peripheral material layers. However, the pixel array 1100 may include three or more peripheral material layers.

In FIG. 8A, a first nano post NP1 and a second nano post NP2 vertically adjacent to each other may be disposed to overlap each other in a vertical direction (a Z direction). A second nano post NP2 may not be provided on a first nano post NP1 corresponding thereto at a partial position. In FIG. 8B, a first nano post NP1 and a second nano post NP2 vertically adjacent to each other may be disposed not to overlap each other in a vertical direction (a Z direction).

Referring to FIGS. 8A and 8B, the pixel array 1100 may include a sensor substrate 110, a spacer layer 120, a color separating lens array 130, a color filter array 170, an etch stop layer 180, and a CMP stop layer 190. A plurality of light sensing cells divisionally provided in the sensor substrate 110 and a color of the color filter array 170 included in the pixel array 1100 may have a correspondence relationship with a region of the color separating lens array 130 as described above and are not described below.

The color separating lens array 130 may include a first lens layer LE1 and a second lens layer LE2. The first lens layer LE1 may include a plurality of first nano posts NP1 and a first peripheral material layer E1 disposed at peripheries thereof, and the second lens layer LE2 may include a plurality of second nano posts NP2 and a second peripheral material layer E2 disposed at peripheries thereof.

A first etch stop layer 181 may be disposed between the first lens layer LE1 and the spacer layer 120. Also, a second etch stop layer 182 may be disposed between a first CMP stop layer 191 and the second lens layer LE2. An upper surface of the first etch stop layer 181 may be disposed at a vertical level which is higher than a lower surface of the first nano post NP1. Also, an uppermost surface of the second etch stop layer 182 may be disposed at a vertical level which is higher than a lower surface of the second nano post NP2.

Each of the lower surface of the first nano post NP1, an upper surface of the first nano post NP1, the lower surface of the second nano post NP2, and an upper surface of the second nano post NP2 may have a flat shape.

Also, the first CMP stop layer 191 may be disposed at a portion, except the first nano post NP1, between the second etch stop layer 182 and the first peripheral material layer E1, and the second CMP stop layer 192 may be disposed at a portion, except the second nano post NP2, on the second peripheral material layer E2.

A range of a first thickness T1 which is a thickness of the second etch stop layer 182 in a vertical direction (a Z direction) may be about 1 nm to about 30 nm, and a range of a second thickness T2 which is a thickness of the first CMP stop layer 191 in the vertical direction (the Z direction) may be about 1 nm to about 100 nm.

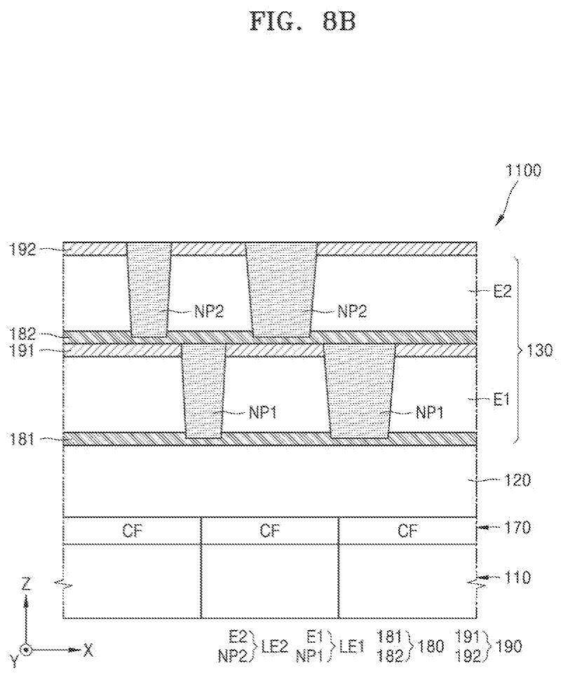

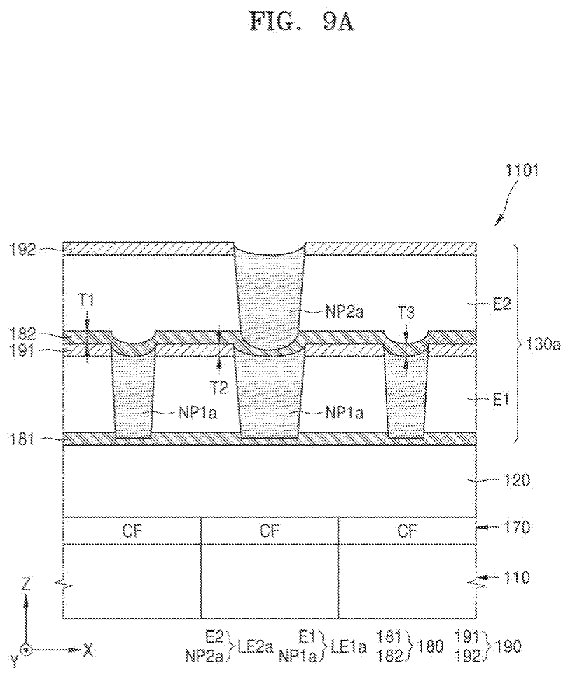

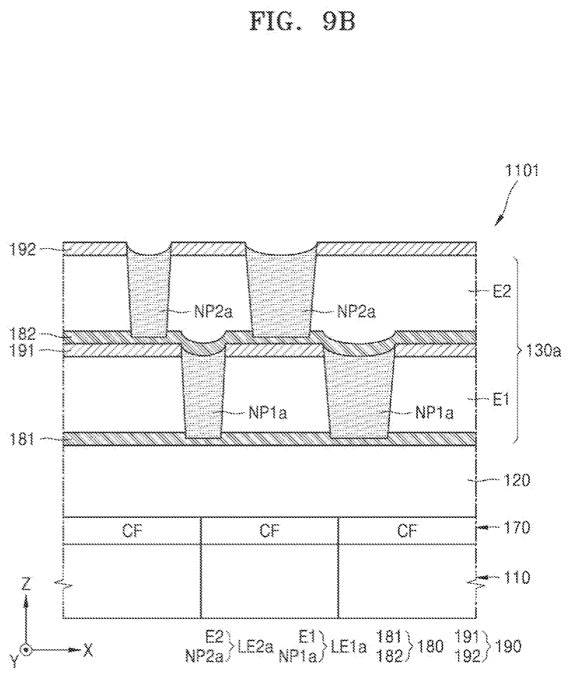

FIGS. 9A and 9B are cross-sectional views illustrating a pixel array of an image sensor according to an embodiment and an example where color separating lens arrays are seen at different positions. FIGS. 9A and 9B illustrate shapes of a first nano post NP1a and a second nano post NP2a included in a first lens layer LE1 and a second lens layer LE2 at different positions of a color separating lens array 130a. Descriptions which are the same as or similar to the descriptions of FIGS. 8A and 8B are omitted.

In FIG. 9A, a first nano post NP1a and a second nano post NP2a vertically adjacent to each other may be disposed to overlap each other in a vertical direction (a Z direction). A second nano post NP2a may not be provided on a first nano post NP1a corresponding thereto at a partial position.

Referring to FIG. 9A, a pixel array 1101 may include a sensor substrate 110, a spacer layer 120, a color separating lens array 130a, a color filter array 170, an etch stop layer 180, and a CMP stop layer 190.

The color separating lens array 130a may include a first lens layer LE1a and a second lens layer LE2a. The first lens layer LE1a may include a plurality of first nano posts NP1a and a first peripheral material layer E1 disposed at peripheries thereof, and the second lens layer LE2a may include a plurality of second nano posts NP2a and a second peripheral material layer E2 disposed at peripheries thereof.

An upper surface of the first nano post NP1a may have a structure which is concave downward in a vertical direction. This may be because a CMP selectivity of the first nano post NP1a is higher than a CMP selectivity of a first CMP stop layer 191. In an embodiment, an uppermost portion of the upper surface of the first nano post NP1a and the upper surface of the first CMP stop layer 191 are disposed at a same vertical level. Also, an upper surface of the second nano post NP2a may have a structure which is concave downward in a vertical direction. This may be because a CMP selectivity of the second nano post NP2a is higher than a CMP selectivity of a second CMP stop layer 192. Because the upper surface of the first nano post NP1a has a structure which is concave downward in a vertical direction, a second etch stop layer 182 overlapping the first nano post NP1a in a vertical direction (a Z direction) may have a structure which protrudes downward in a vertical direction. Also, a lower surface of the second nano post NP2a overlapping the first nano post NP1a in the vertical direction (the Z direction) may have a structure which protrudes downward in a vertical direction. For example, the lower surface of the second nano post NP2a may have a round shape instead of a flat shape.

A range of a first thickness T1 which is a thickness of the second etch stop layer 182 in a vertical direction (a Z direction) may be about 1 nm to about 30 nm, and a range of a second thickness T2 which is a thickness of the first CMP stop layer 191 in the vertical direction (the Z direction) may be about 1 nm to about 100 nm. Also, a range of a third thickness T3 which is a thickness in the vertical direction (the Z direction) up to an uppermost surface of the first nano post NP1a from a lowermost surface of the second etch stop layer 182 may be about 50 nm or less.

In FIG. 9B, a first nano post NP1 and a second nano post NP2 vertically adjacent to each other may be disposed not to overlap each other in the vertical direction (the Z direction).

Referring to FIG. 9B, a lower surface of the second nano post NP2a may have a flat shape. This may be because the first nano post NP1a does not overlap the second nano post NP2a in the vertical direction (the Z direction). For example, when a center axis of each first nano post NP1a is spaced apart from a center axis of each second nano post NP2a in a horizontal direction (an X direction and/or a Y direction), the lower surface of the second nano post NP2a may have a flat shape.

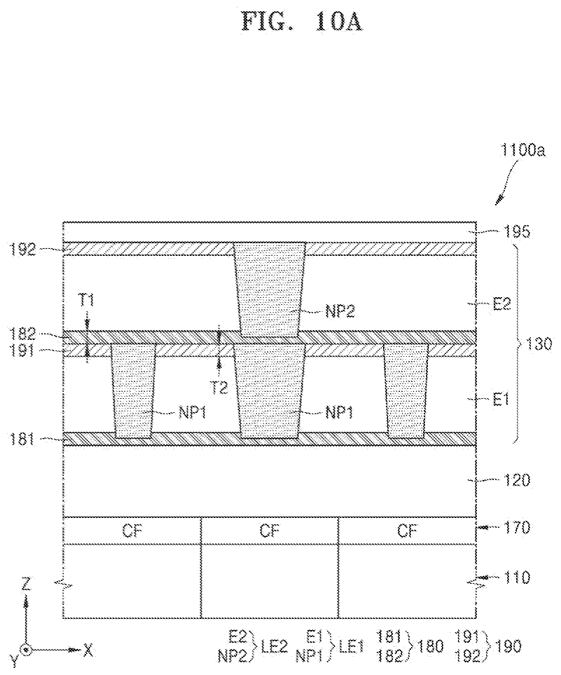

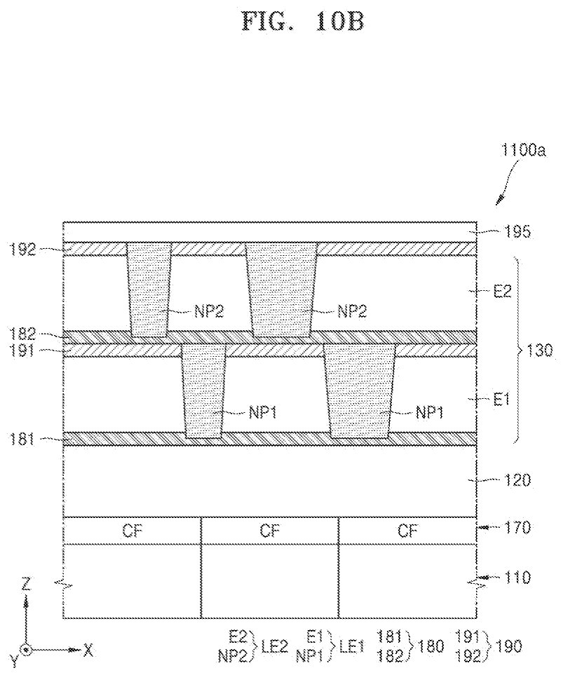

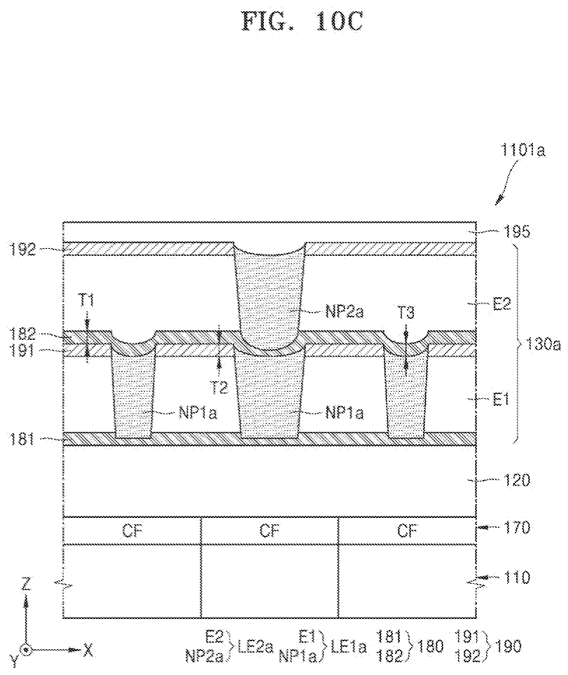

FIGS. 10A to 10D are cross-sectional views illustrating a pixel array of an image sensor according to an embodiment, FIGS. 10A and 10B illustrate an example where each color separating lens array is seen at different positions, and FIGS. 10C and 10D illustrate an example where each color separating lens array is seen at different positions.

Referring to FIGS. 8A, 8B, 10A, and 10B, a pixel array 1100a may further include a passivation layer 195 which is disposed on the second lens layer LE2 of the pixel array 1100 of FIGS. 8A and 8B. The passivation layer 195 may include a material which acts as a reflection stop layer. The reflection stop layer may decrease light, reflected from an upper surface of a color separating lens array 130, of incident light, thereby improving the light use efficiency of the pixel array 1101a. For example, the reflection stop layer may enable light incident on the pixel array 1100a from the outside to pass through the color separating lens array 130 and be sensed by the sensor substrate 110 without being reflected by the upper surface of a color separating lens array 130.

The reflection stop layer may have a structure where one layer or a plurality of layers are stacked, and for example, may be one layer including a material which differs from that of the second lens layer LE2. The reflection stop layer may include a plurality of material layers having different refractive indexes.

Referring to FIGS. 9A, 9B, 10C, and 10D, a pixel array 1101a may further include a passivation layer 195 which is disposed on the second lens layer LE2 of the pixel array 1101 of FIGS. 9A and 9B. The passivation layer 195 of FIGS. 10C and 10D may be similar to the passivation layer 195 of FIGS. 10A and 10B.

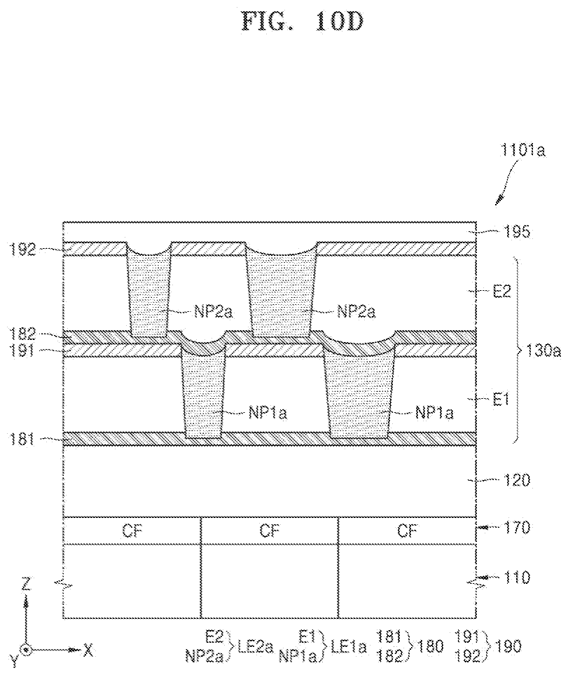

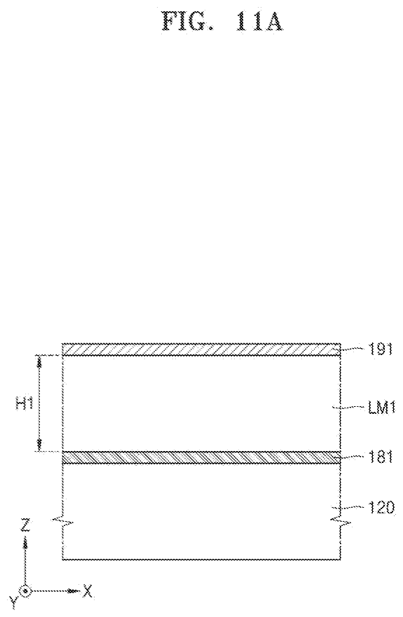

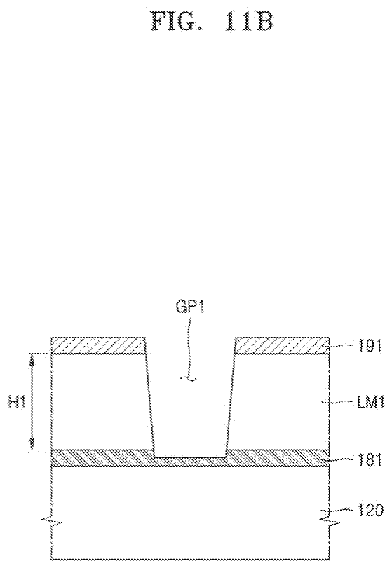

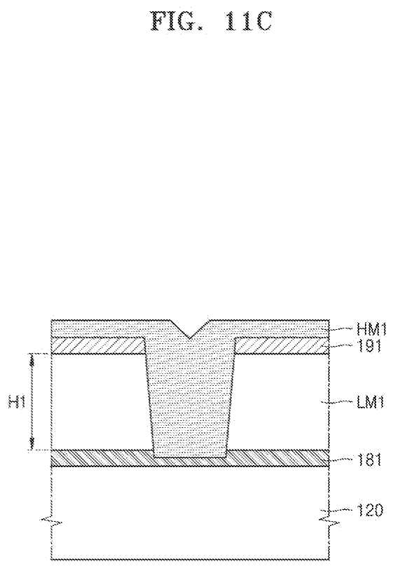

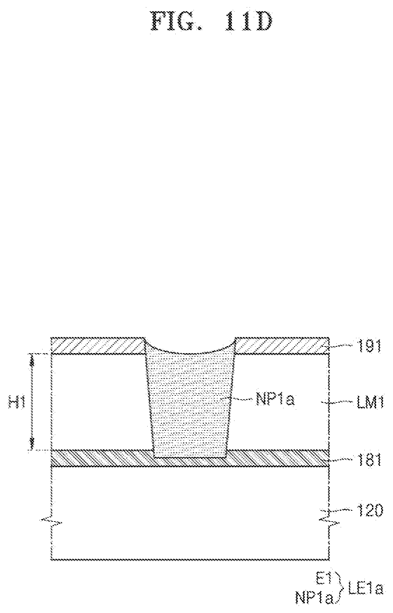

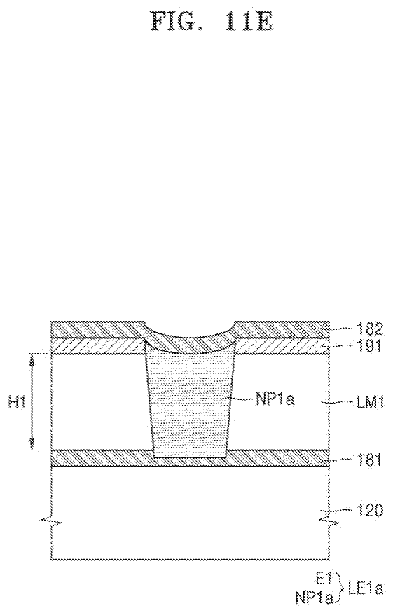

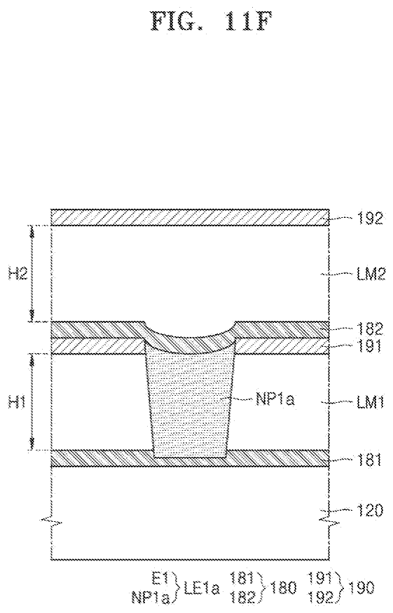

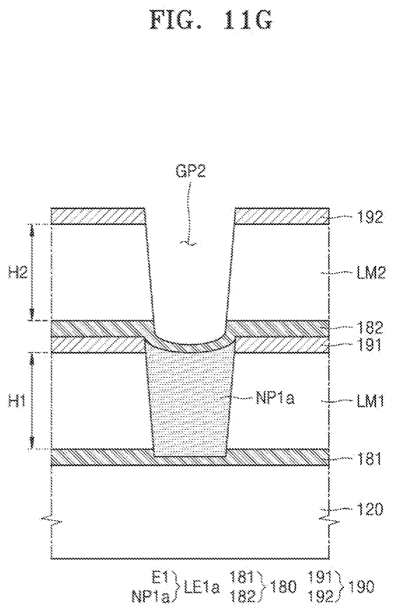

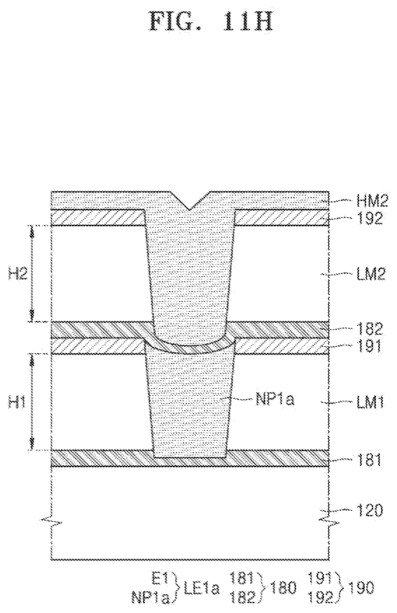

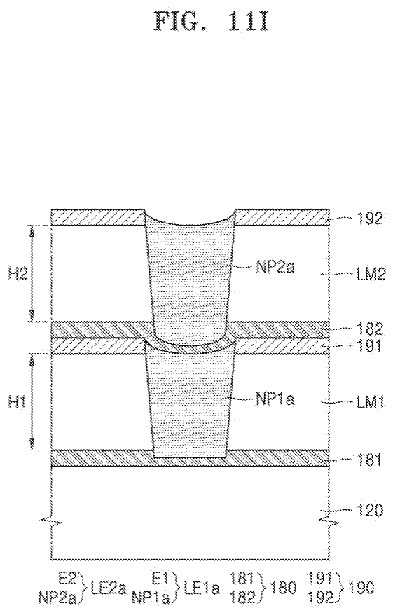

FIGS. 11A to 11I are cross-sectional views describing a method of manufacturing the image sensor of FIGS. 9A and 9B.

Referring to FIG. 11A, a spacer layer 120, a first etch stop layer 181 disposed on the spacer layer 120, a first dielectric layer LM1 on the first etch stop layer 181, and a first CMP stop layer 191 on the first dielectric layer LM1 may be formed. Such a structure, as described above, may be formed on a sensor substrate 110, or may be formed on a color filter array 170 formed on the sensor substrate 110.

The spacer layer 120 may be, for example, a SiO₂ layer and may be formed by various physical or chemical formation processes, for example, a thermal oxidation process.

The first etch stop layer 181 may include a material for selectively etching the first dielectric layer LM1, namely, may include a material which is not etched by a material used in etching of the first dielectric layer LM1, and for example, may be a layer including HfO₂. The may be formed by a physical or chemical formation process (for example, physical vapor deposition (PVD), chemical vapor deposition (CVD), plasma enhanced-CVD (PE-CVD), and atomic layer deposition (ALD)).

The first dielectric layer LM1 may be a SiO₂ layer, and in addition, may include a polymer material, such as SU-8 or PMMA, or SOG, which is a material having a low refractive index. The first dielectric layer LM1 may include a material having a relatively low refractive index, but is not limited thereto and may include at least one of c-Si, p-Si, a-Si, a III-V compound semiconductor (for example, GaP, GaN, GaAs, etc.), SiC, TiO₂, and SiN.

The first CMP stop layer 191 may include a material for selectively performing CMP on a first nano pattern layer (HM1 of FIG. 11C) including a material used to manufacture a first nano post (NP1a of FIG. 9A), which will be described below, and for example, may include a material which is not well removed in performing CMP on the first nano pattern layer (HM1 of FIG. 11C). The first CMP stop layer 191 may include a material having a CMP selectivity which is less than a CMP selectivity of the first nano pattern layer (HM1 of FIG. 11C). The first CMP stop layer 191 may include Al₂O₃, SiN, or HfO₂. A thickness of the first CMP stop layer 191 may be about 1 nm to about 100 nm. A thickness of the first CMP stop layer 191 may be set based on a material and a thickness of the first nano pattern layer (HM1 of FIG. 11C). For example, a thickness of the first CMP stop layer 191 may be set based on a thickness of a portion, which is to be implemented as a first nano post NP1a of FIG. 11D, of a region of a first nano pattern layer HM1 illustrated in FIG. 11C and a thickness of a portion, which is to be removed by CMP, of an upper surface of the first dielectric layer LM1. The thickness of the first CMP stop layer 191 may increase in proportion to a thickness of the first nano pattern layer (HM1 of FIG. 11C) which is to be removed by CMP, and moreover, may be set to a thickness to prevent or reduce damage caused by the optical performance of a manufactured color separating lens array.

Referring to FIG. 11B, a first engraved pattern GP1 may be formed by patterning the first dielectric layer LM1 and the first CMP stop layer 191. At least a portion of the first etch stop layer 181 may be etched in a process of forming the first engraved pattern GP1.

A photolithography process may be used in forming the first engraved pattern GP1. A photoresist may be formed on the first CMP stop layer 191 of FIG. 11A and may be patterned by an exposure process, and then, the first engraved pattern GP1 may be formed by etching the first CMP stop layer 191 and the first dielectric layer LM1 at a position corresponding to an exposed pattern. For example, a proline-based reactivity ion etching process may be used in etching the first CMP stop layer 191 and the first dielectric layer LM1. In such a process, the first etch stop layer 181 may prevent the spacer layer 120 from being damaged.

Referring to FIG. 11C, the first nano pattern layer HM1 may be formed by coating a material, having a refractive index which differs from that of the first dielectric layer LM1, on an inner portion of a first engraved pattern (GP1 of FIG. 11B). The first nano pattern layer HM1 may be formed to fill the first engraved pattern (GP1 of FIG. 11B) and extend to an upper surface of the first CMP stop layer 191.

A material used for the first nano pattern layer HM1 may be a material having a refractive index which differs from that of the first dielectric layer LM1, and for example, may include c-Si, p-Si, a-Si, a III-V compound semiconductor (for example, GaP, GaN, GaAs, etc.), SiC, TiO₂, and/or SiN. When the first dielectric layer LM1 includes a material having a high refractive index, the first nano pattern layer HM1 may include SiO₂ which is a material having a low refractive index, or may include a polymer material, such as SU-8 or PMMA, or SOG. An ALD process or other various deposition processes may be used in forming the first nano pattern layer HM1.

Subsequently, as illustrated in FIG. 11D, an upper surface of the first nano pattern layer (HM1 of FIG. 11C) may be polished by a CMP process, and thus, the first nano post NP1a having a desired shape and the first lens layer LE1a including the first dielectric layer LM1 adjacent to and surrounding the first nano post NP1a may be formed. In a process of performing CMP on the first nano pattern layer HM1, the first dielectric layer LM1 may be protected by the first CMP stop layer 191 and a first height H1 may be maintained. The first height H1 may be a height which is set in an operation of FIG. 11A and may be intactly maintained even after a CMP process is performed.

Also, an upper surface of the first nano post NP1a may have a structure which is concave downward in a vertical direction, based on a CMP selectivity difference of each of the first nano pattern layer (HM1 of FIG. 11C) and the first CMP stop layer 191. That is, the upper surface of the first nano post NP1a may have a round shape.

Referring to FIG. 11E, the second etch stop layer 182 may be disposed on the first CMP stop layer 191 and the first nano post NP1a. The second etch stop layer 182 may be similar to the first etch stop layer 181. Because the upper surface of the first nano post NP1a has a shape which is concave downward in a vertical direction, the second etch stop layer 182 disposed on the first nano post NP1a may have a shape which is concave downward in a vertical direction.

Referring to FIG. 11F, a second dielectric layer LM2 may be disposed on the second etch stop layer 182, and a second CMP stop layer 192 may be disposed on the second dielectric layer LM2. The second dielectric layer LM2 may be similar to the first dielectric layer LM1, and the second CMP stop layer 192 may be similar to the first CMP stop layer 191. The second etch stop layer 182 may have a shape which is concave downward in a vertical direction, and a lower surface of the second dielectric layer LM2 may have a shape which is convex downward in a vertical direction.

Referring to FIG. 11G, a second engraved pattern GP2 may be formed by patterning the second dielectric layer LM2 and the second CMP stop layer 192. At least a portion of the second etch stop layer 182 may be etched in a process of forming the second engraved pattern GP2. A method of forming the second engraved pattern GP2 may be approximately similar to a method of forming the second engraved pattern GP1 of FIG. 11B.

Referring to FIG. 11H, the second nano pattern layer HM2 may be formed by coating a material, having a refractive index which differs from that of the second dielectric layer LM2, on an inner portion of the second engraved pattern GP2. The second nano pattern layer HM2 may be formed to fill the second engraved pattern (GP2 of FIG. 11G) and extend to an upper surface of the second CMP stop layer 192. The second nano pattern layer HM2 may be approximately similar to the first nano pattern layer HM1 of FIG. 11C.

Referring to FIG. 11I, an upper surface of the second nano pattern layer (HM2 of FIG. 11H) may be planarized by a CMP process, and thus, the second nano post NP2a and the second lens layer LE2a including the second dielectric layer LM2 provided adjacent to and surrounding the second nano post NP2a may be formed. In a process of performing CMP on the second nano pattern layer (HM2 of FIG. 11H), the second dielectric layer LM2 may be protected by the second CMP stop layer 192 formed on an upper surface of the second dielectric layer LM2 and a second height H2 may be maintained. The second height H2 may be a height which is set in an operation of FIG. 11F and may be intactly maintained even after a CMP process is performed.

Also, an upper surface of the second nano post NP2a may have a structure which is concave downward in a vertical direction, based on a CMP selectivity difference of each of the second nano pattern layer (HM2 of FIG. 11H) and the second CMP stop layer 192. That is, the upper surface of the second nano post NP2a may have a round shape.

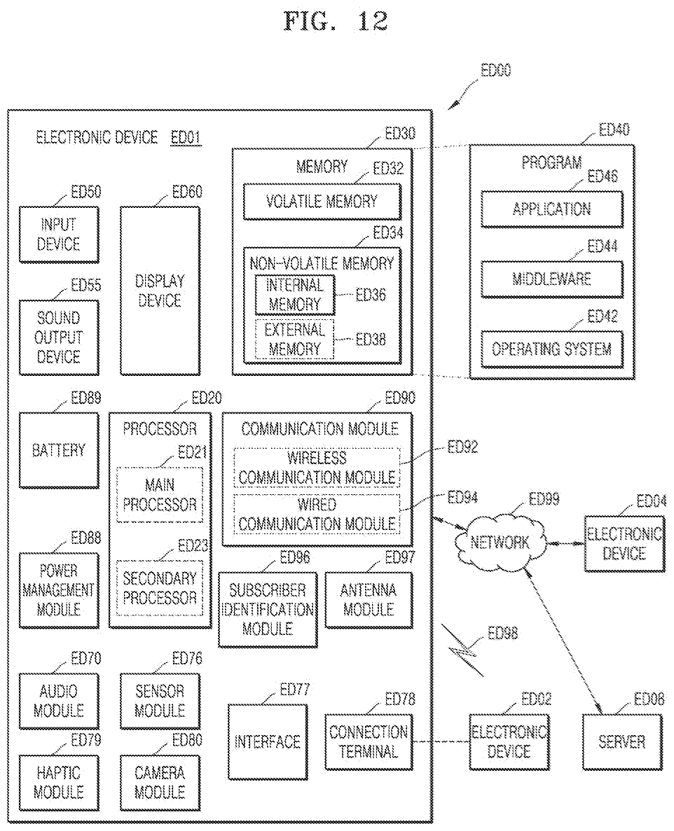

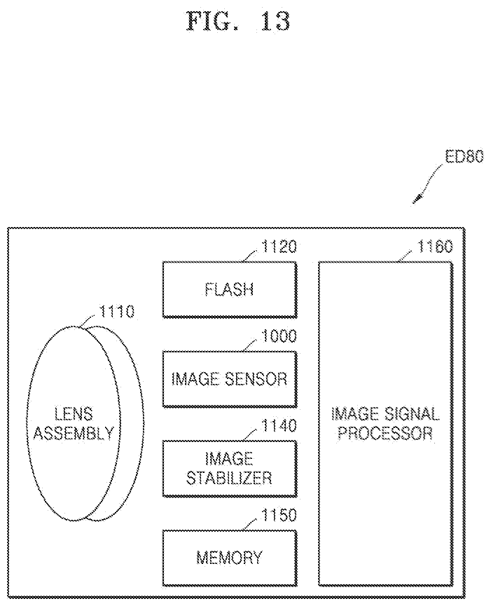

FIG. 12 is a block diagram schematically illustrating an electronic device including an image sensor according to an embodiment, and FIG. 13 is a block diagram illustrating a camera module included in the electronic device of FIG. 12.

Referring to FIG. 12, in a network environment ED00, an electronic device ED01 may communicate with another electronic device ED02 over a first network ED98 (a close-distance wireless communication network or the like), or may communicate with another electronic device ED04 and/or a server ED08 over a second network ED99 (a long-distance wireless communication network or the like). The electronic device ED01 may communicate with the electronic device ED04 through the server ED08. The electronic device ED01 may include a processor ED20, a memory ED30, an input device ED50, a sound output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. Some (the display device ED60, etc.) of the elements of the electronic device ED01 may be omitted, or another element may be added. Some of the elements may be implemented as one integrated circuit. For example, the sensor module ED76 (a fingerprint sensor, an iris sensor, an illumination sensor, etc.) may be embedded in the display device ED60 (a display, etc.).

The processor ED20 may execute software (the program ED40, etc.) to control one element or other elements (a hardware element, a software element, etc.) of the electronic device ED01 connected to the processor ED20 and may perform various data processing or operations. In a portion of data processing or operation, the processor ED20 may load an instruction and/or data, received from the other element (the sensor module ED76) or the communication module ED90, into a volatile memory ED32, may process the instruction and/or data stored in the volatile memory ED32, and may store resultant data in a non-volatile memory ED34. The processor ED20 may include a main processor ED21 (a central processing unit (CPU), an application processor, etc.) and a secondary processor ED23 (a graphics processing unit (GPU), an image signal processor, a sensor hub processor, a communication processor, etc.) which may operate along with or independently of the main processor ED21. The secondary processor ED23 may use power which is less than the main processor ED21 and may perform a specialized function.

The secondary processor ED23 may control a function and/or a state each associated with some of the elements of the electronic device ED01 along with the main processor ED21 while the main processor ED21 is in an active state (an application execution state) or instead of the main processor ED21 while the main processor ED21 is an inactive state (a sleep state). The secondary processor ED23 (an image signal processor, a communication processor, etc.) may be implemented as a portion of the other element (the camera module ED80, the communication module ED90, etc.) functionally relevant thereto.

The memory ED30 may store various data needed for the elements (the processor ED20, the sensor module ED76, etc.) of the electronic device ED01. The data may include, for example, software (the program ED40, etc.) and input data and/or output data corresponding to an instruction relevant thereto. The memory ED30 may include the volatile memory ED32 and/or the non-volatile memory ED34.

The program ED40 may be stored as software in the memory ED30 and may include an operating system ED42, a middleware ED44, and/or an application ED46.

The input device ED50 may receive an instruction and/or data, which is to be used for the element (the processor ED20, etc.) of the electronic device ED01, from the outside (a user or the like) of the electronic device ED01. The input device ED50 may include a microphone, a mouse, a keyboard, and/or a digital pen (a stylus pen or the like).

The sound output device ED55 may output a sound signal to the outside of the electronic device ED01. The sound output device ED55 may include a speaker and/or a receiver. The speaker may be used for general purpose like multimedia reproduction or replay, and the receiver may be used for receiving an incoming call. The receiver may be coupled to a portion of the speaker, or may be implemented as a separate device.

The display device ED60 may visually provide information to the outside of the electronic device ED01. The display device ED60 may include a display, a hologram device, or a control circuit for controlling a projector and a corresponding device. The display device ED60 may include a touch circuit configured to sense a touch and/or a sensor circuit (a pressure sensor or the like) configured to measure strength of a force generated by a touch.

The audio module ED70 may convert a sound into an electrical signal, or may convert an electrical signal into a sound. The audio module ED70 may obtain a sound through the input device ED50, or may output a sound through a speaker and/or a headphone of another electronic device (the electronic device ED02 or the like) directly or wirelessly connected to the electronic device ED01.

The sensor module ED76 may sense an operating state (power, a temperature, etc.) of the electronic device ED01 or an external environment state (a user state, etc.) and may generate an electrical signal and/or a data value each corresponding to the sensed state. The sensor module ED76 may include a gesture sensor, a gyro sensor, an atmospheric pressure sensor, a magnetic sensor, an acceleration sensor, a grip sensor, a proximity sensor, a color sensor, an infrared (IR) sensor, a bio sensor, a temperature sensor, a humidity sensor, and/or an illumination sensor.

The interface ED77 may support one protocol or a plurality of protocols, which may be used to directly or wirelessly connect the electronic device ED01 with another electronic device (the electronic device ED02). The interface ED77 may include a high definition multimedia interface (HDMI), a universal serial bus (USB) interface, a secure digital (SD) card interface, and/or an audio interface.

A connection terminal ED78 may include a connector which may physically connect the electronic device ED01 with another electronic device (the electronic device ED02). The connection terminal ED78 may include an HDMI connector, a USB connector, an SD card connector, and/or an audio connector (a headphone connector or the like).

The haptic module ED79 may convert an electrical signal into a mechanical stimulus (a vibration, a motion, or the like) or an electrical stimulus, which may be recognized by a user through tactile sensitivity or motion sensitivity. The haptic module ED79 may include a motor, a piezoelectric device, and/or an electrical stimulus device.

The camera module ED80 may capture a still image and a moving image. The camera module ED80 may include a lens assembly including one lens or a plurality of lenses, the image sensor 1000 of FIG. 1, image signal processors, and/or flashes. The lens assembly included in the camera module ED80 may collect light emitted from a subject where an image thereof is to be captured.

The power management module ED88 may manage power supplied to the electronic device ED01. The power management module ED88 may be implemented as a portion of a power management integrated circuit (PMIC).

The battery ED89 may supply power to the elements of the electronic device ED01. The battery ED89 may include a primary cell incapable of being recharged, a secondary cell capable of being recharged, and/or a fuel cell.

The communication module ED90 may support establishment of a direct (wired) communication channel and/or a wireless communication channel between the electronic device ED01 and another electronic device (the electronic device ED02, the electronic device ED04, the server ED08, etc.) and communication performed through an established communication channel. The communication module ED90 may include one communication processor or a plurality of communication processors, which operate(s) independently from the processor ED20 (an application processor, etc.) and support(s) direct communication and/or wireless communication. The communication module ED90 may include a wireless communication module ED92 (a cellular communication module, a close-distance wireless communication module, a global navigation satellite system (GNSS) communication module) and/or the wired communication module ED94 (a local area network (LAN) communication module, a power line communication module, etc.). A corresponding communication module among such communication modules may communicate with another electronic device over a first network ED98 (a close-distance communication network such as Bluetooth, Wi-Fi Direct or infrared data association (IrDA)) or a second network ED99 (a long-distance communication network such as a cellular network, Internet, or a computer network (LAN, wide area network (WAN), etc.). Such various kinds of communication modules may be integrated into one element (a single chip), or may be implemented as a plurality of elements (a plurality of chips) which are individually provided. The wireless communication module ED92 may check and authenticate the electronic device ED01 in a communication network such as the first network ED98 and/or the second network ED99 by using subscriber information (international mobile station identity (IMSI), etc.) stored in the subscriber identification module ED96.

The antenna module ED97 may transmit a signal and/or power to the outside (another electronic device), or may receive a signal and/or power from the outside. The antenna may include a radiator which includes a conductive pattern formed on a substrate (a PCB or the like). The antenna module ED97 may include one antenna or a plurality of antennas. When the antenna module ED97 includes a plurality of antennas, the communication module ED90 may select an antenna, which is used for a communication network such as the first network ED98 and/or the second network ED99, from among the plurality of antennas. The communication module ED90 may transmit or receive a signal and/or power to or from another electronic device through the selected antenna. Another part (radio frequency integrated chip (RFIC) or the like) other than an antenna may be included as one element in the antenna module ED97.

Some of the elements may be connected with one another and may exchange a signal (an instruction, data, etc.) therebetween through a communication scheme (a bus, general purpose input and output (GPIO), serial peripheral interface (SPI), mobile industry processor interface (MIPI), etc.) between peripheral devices.

The instruction or the data may be transmitted or received between the electronic device ED01 and the external electronic device ED04 through the server ED08 connected to the second network ED99. The other electronic devices ED02 and ED04 may be the same or different kinds of electronic devices as or from the electronic device ED01. All or some of operations executed by the electronic device ED01 may be executed in one or more of the other electronic devices ED02, ED04, and ED08. For example, in a case where the electronic device ED01 has to perform an arbitrary function or service, the electronic device ED01 may issue a request, to one or more other electronic devices, to perform a portion or all of the function or the service instead of autonomously executing the function or the service. The one or more electronic devices receiving the request may execute an additional function or service associated with the request and may transfer a result of the execution to the electronic device ED01. To this end, cloud computing, distributed computing, and/or client-server computing technology may be used.

Referring to FIG. 13, the camera module ED80 may include a lens assembly 1110, a flash 1120, an image sensor 1000, an image stabilizer 1140, a memory 1150 (a buffer memory or the like), and/or an image signal processor 1160. The lens assembly 1110 may collect light emitted from a subject where an image thereof is to be captured. The camera module ED80 may include a plurality of lens assemblies 1110, and in this case, the camera module ED80 may include a dual camera, a 360-degree camera, or a spherical camera. Some of the plurality of lens assemblies 1110 may have the same lens attributes (an angle of view, a focus distance, an auto-focus, F number, optical zoom, etc.), or may have different lens attributes. The lens assembly 1110 may include a wide-angle lens or a telephoto lens.

The flash 1120 may emit light which is used to reinforce light emitted or reflected from a subject. The flash 1120 may include one or more light-emitting diodes (LEDs) (for example, a red-green-blue (RGB) LED, a white LED, an infrared LED, and an ultraviolet (UV) LED) and/or a xenon lamp.

The image sensor 1000 may be the image sensor described above with reference to FIG. 1 and may include one of the pixel arrays 1100, 1100a, 1101, and 1101a according to the embodiments described above. The image sensor 1000 may be manufactured by the manufacturing method described above with reference to FIGS. 11A to 11I. The image sensor 1000 may convert light, which is emitted or reflected from a subject and is transferred through the lens assembly 1110, into an electrical signal, and thus, an image corresponding to the subject may be obtained. The image sensor 1000 may include one or more sensors selected from among image sensors, having different attributes, such as an RGB sensor, a black and white (BW) sensor, an IR sensor, and an UV sensor. Each of the sensors included in the image sensor 1000 may be implemented as a CCD sensor and/or a CMOS sensor.

The image stabilizer 1140 may move the image sensor 1000 or one or more lenses included in the lens assembly 1110 in a certain direction or may control an operation characteristic (adjustment of a readout timing) of the image sensor 1000, in response to a motion of the camera module ED80 or the electronic device ED01 including the camera module ED80, thereby compensating for an adverse effect caused by a motion. The image stabilizer 1140 may sense a motion of the camera module ED80 or the electronic device ED01 by using a gyro sensor (not shown) or an acceleration sensor (not shown) disposed in or outside the camera module ED80. The image stabilizer 1140 may be implemented as an optical type.

The memory 1150 may store some or all data of an image obtained through the image sensor 1000 so as to perform a next image processing operation. For example, in a case where a plurality of images are obtained at a high speed, obtained original data (for example, Bayer-patterned data, high-resolution data, etc.) may be stored in the memory 1150 and only a low-resolution image may be displayed, and then, the obtained original data may be used to transfer original data of a selected (a user selection) image to the image signal processor 1160. The memory 1150 may be integrated into the memory ED30 of the electronic device ED01, or may be implemented as a separate memory which operates independently.

The image signal processor 1160 may perform image processing on an image obtained through the image sensor 1000 or image data stored in the memory 1150. The image processing may include an operation of generating a depth map, a three-dimensional modeling operation, an operation of generating a panorama, an operation of extracting a feature point, an operation of synthesizing images, and/or an operation of compensating for an image (noise reduction, resolution adjustment, brightness adjustment, blurring, sharpening, softening, etc.). The image signal processor 1160 may perform control (exposure time control or readout timing control) of elements (the image sensor 1000, etc.) included in the camera module ED80. An image obtained through processing by the image signal processor 1160 may be again stored in the memory 1150 for additional processing, or may be supplied to an element (for example, the memory ED30, the display device ED60, the electronic device ED02, the electronic device ED04, the server ED08, etc.) outside the camera module ED80. The image signal processor 1160 may be integrated into the processor ED20, or may be implemented as a separate memory which operates independently. In a case where the image signal processor 1160 is configured as a separate processor independently from the processor ED20, the image obtained through processing by the image signal processor 1160 may be additionally processed by the processor ED20 and may be displayed by the display device ED60.

The electronic device ED01 may include a plurality of camera modules ED80 having different attributes or functions. In this case, one of the plurality of camera modules ED80 may be a wide angle camera, and the other camera may be a telephoto camera. Similarly, one of the plurality of camera modules ED80 may be a front view camera, and the other camera may be a rear view camera.

The image sensor 1000 according to embodiments may be applied to mobile phones or smartphones, tablet computers or smart tablet computers, digital cameras or camcorders, notebook computers, and televisions or smart televisions. For example, the smartphone or the smart tablet computer may include a plurality of high-resolution cameras equipped with a high-resolution image sensor. Depth information about in-image subjects may be extracted by using high-resolution cameras, or out-focusing of the image may be adjusted, or the in-image subjects may be automatically identified.

Also, the image sensor 1000 may be applied to smart refrigerators, security cameras, robots, and medical cameras. For example, the smart refrigerator may automatically recognize food in a refrigerator by using an image sensor and may notify a user of the presence of certain food and the kind of take-in or take-out food by using a smartphone. The security camera may provide an ultra-high-resolution image and may enable recognition of an in-image thing or person despite a dark environment. The robot may be deployed in a disaster or industry site which is impossible to directly access a person and may provide a high-resolution image. The medical camera may provide a high-resolution image for diagnosis or surgery and may automatically adjust a field of view.

Also, the image sensor 1000 may be applied to vehicles. The vehicle may include a plurality of vehicular cameras disposed at various positions. Each of the vehicular cameras may include the image sensor according to an embodiment. The vehicle may provide a driver with various information about an internal portion or a periphery of the vehicle by using the plurality of vehicular cameras and may automatically recognize an in-image thing or person to provide information needed for autonomous driving.

An embodiment has been described where an image sensor including a color separating lens array and an electronic device including the same described above are illustrated in the drawings, but embodiments are not limited thereto, and various modifications may be implemented therefrom by those of ordinary skill in the art. The embodiments are not for limiting, and the scope of the present disclosure is not limited by the embodiments. The scope of the present disclosure has to be construed by the appended claims, and all spirits within an equivalent range.

While the inventive concept has been particularly shown and described with reference to embodiments thereof, it will be understood that various changes in form and details may be made therein without departing from the spirit and scope of the following claims and their equivalents.

What is claimed is:

1. An image sensor comprising:
a sensor substrate;
a spacer layer on the sensor substrate; and
a color separating lens array on the spacer layer and configured to separate light based on a wavelength of the light,
wherein the color separating lens array comprises:
a first lens layer comprising a plurality of first nano posts and a first peripheral material layer around the plurality of first nano posts;
a chemical mechanical polishing (CMP) stop layer on the first peripheral material layer;
an etch stop layer on an upper surface of the CMP stop layer and directly on an upper surface of each of the plurality of first nano posts; and
a second lens layer on the etch stop layer, the second lens layer comprising a plurality of second nano posts and a second peripheral material layer around the plurality of second nano posts.

2. The image sensor of claim 1, wherein an upper surface of the etch stop layer comprises a concave-convex portion.

3. The image sensor of claim 1, wherein a lower surface of each second nano post of the plurality of second nano posts is at a vertical level which is lower than an uppermost surface of the etch stop layer.

4. The image sensor of claim 1, wherein lower surfaces of at least one second nano posts of the plurality of second nano posts has a flat shape.

5. The image sensor of claim 1, wherein the upper surface of each first nano post of the plurality of first nano posts and the upper surface of the CMP stop layer are disposed at a same vertical level.

6. The image sensor of claim 1, wherein the upper surface of each first nano post of the plurality of first nano posts has a shape which is concave downward in a vertical direction.

7. The image sensor of claim 1, wherein an uppermost surface of each first nano posts of the plurality of first nano posts and the upper surface of the CMP stop layer are disposed at a same vertical level.

8. An image sensor comprising:
a sensor substrate comprising a plurality of light sensing cells;
a spacer layer on the sensor substrate;
a first etch stop layer on the spacer layer; and
a color separating lens array on the first etch stop layer and configured to separate light based on a wavelength of the light,
wherein the color separating lens array comprises:
a first lens layer comprising a plurality of first nano posts and a first peripheral material layer around the plurality of first nano posts;
a chemical mechanical polishing (CMP) stop layer on the first peripheral material layer;
a second etch stop layer on an upper surface of the CMP stop layer and directly on an upper surface of each first nano post of the plurality of first nano posts; and
a second lens layer on the second etch stop layer, the second lens layer comprising a plurality of second nano posts and a second peripheral material layer around the plurality of second nano posts.

9. The image sensor of claim 8, wherein an upper surface of the first etch stop layer has a concave-convex shape.

10. The image sensor of claim 8, wherein a lower surface of each first nano post of the plurality of first nano posts is at a vertical level which is lower than an uppermost surface of the first etch stop layer.

11. The image sensor of claim 8, wherein lower surfaces of at least one first nano posts of the plurality of first nano posts has a flat shape.

12. The image sensor of claim 8, wherein the upper surface of each first nano post of the plurality of first nano posts has a shape which is concave downward in a vertical direction, and
wherein a lower surface of a corresponding second nano post overlapping a corresponding first nano post in the vertical direction has a shape which protrudes downward in the vertical direction.

13. The image sensor of claim 12, wherein the second etch stop layer on the plurality of first nano posts has a shape which protrudes downward in the vertical direction.

14. The image sensor of claim 8, wherein a lower surface of a corresponding second nano post, which does not overlap each first nano post of the plurality of first nano posts in a vertical direction, is flat.

15. The image sensor of claim 8, further comprising one or more lens layers on the second lens layer.

16. An image sensor comprising:
a sensor substrate comprising a first pixel configured to sense a first wavelength light and a second pixel configured to sense a second wavelength light;
a transparent spacer layer on the sensor substrate;
a first etch stop layer on the transparent spacer layer; and
a color separating lens array on the first etch stop layer and configured to separate light based on a wavelength of the light,
wherein the color separating lens array comprises:
a first lens layer comprising a plurality of first nano posts and a first peripheral material layer around the plurality of first nano posts;
a first chemical mechanical polishing (CMP) stop layer on the first peripheral material layer;
a second etch stop layer on an upper surface of the first CMP stop layer and directly on an upper surface of each first nano post of the plurality of first nano posts;
a second lens layer on the second etch stop layer, the second lens layer comprising a plurality of second nano posts and a second peripheral material layer around the plurality of second nano posts; and
a second CMP stop layer on the second peripheral material layer.

17. The image sensor of claim 16, wherein a range of a first thickness of the second etch stop layer in a vertical direction is 1 nm to 30 nm, and
wherein a range of a second thickness of the first CMP stop layer in the vertical direction is 1 nm to 100 nm.

18. The image sensor of claim 16, wherein the upper surface of each first nano post of the plurality of first nano posts has a shape which is concave downward in a vertical direction, and
wherein a range of a third thickness, which is a thickness in the vertical direction to an uppermost surface of a corresponding first nano post from a lowermost surface of the second etch stop layer, is 50 nm or less.

19. The image sensor of claim 16, wherein the first etch stop layer or the second etch stop layer comprises hafnium oxide (HfO₂), silicon oxide (SiO₂), or aluminum oxide (AlO), and
wherein the first CMP stop layer or the second CMP stop layer comprises aluminum oxide (Al₂O₃), silicon nitride (SiN), silicon carbon-nitride (SiCN), or HfO₂.

20. The image sensor of claim 16, further comprising a passivation layer on the second CMP stop layer and the upper surface of each second nano post of the plurality of second nano posts.
